(19) United States
(12) Patent Application Publication
(10) Pub. No.: US 2023/0215849 A1
(43) Pub. Date: Jul. 6, 2023

(54) PACKAGE SUBSTRATES WITH EMBEDDED DIE-SIDE, FACE-UP DEEP TRENCH CAPACITOR(S) (DTC(s)), AND RELATED INTEGRATED CIRCUIT (IC) PACKAGES AND FABRICATION METHODS

(71) Applicant: QUALCOMM Incorporated, San Diego, CA (US)

(72) Inventors: Seongryul Choi, Seongnam (KR); Kuiwon Kang, San Diego, CA (US); Michelle Yejin Kim, San Diego, CA (US)

(21) Appl. No.: 17/647,141

(22) Filed: Jan. 5, 2022

(51) Int. Cl. H01L 25/16; H01L 21/48; H01L 23/00; H01L 23/58; H01L 23/498

(52) U.S. Cl. CPC H01L 25/16; H01L 21/486; H01L 21/4853; H01L 24/16; H01L 23/58; H01L 23/49827; H01L 23/49822; H01L 21/4857; H01L 2224/16227; H01L 2224/16235; H01L 2224/16265; H01L 2924/19102; H01L 2924/19041

(57) ABSTRACT

Integrated circuit (IC) packages employing a package substrate with embedded deep trench capacitor(s) (DTC(s)) face-up to a semiconductor die (“die”) for connection, and related fabrication methods. A DTC is embedded in a cavity in the package substrate and coupled to a die. To minimize connection path length between the DTC and the die to reduce impedance and improve capacitor performance, the DTC is disposed in a cavity in the package substrate face-up towards the die. The DTC interconnects of the DTC are oriented face-up towards the die in a vertical direction. Also, to minimize connection path length between the DTC and the die, the DTC can be disposed in the package substrate underneath the die in the vertical direction. The DTC interconnects can be disposed in a die-side metallization layer of the package substrate and coupled to external, die-side interconnects of the package substrate.

### BACKGROUND

### I. Field of the Disclosure

The field of the disclosure relates to integrated circuit (IC) packages that include one or more semiconductor dies supported by a package substrate, and more particularly to embedding of capacitors in the IC package for signal and/or power integrity.

### II. BACKGROUND

Integrated circuits (ICs) are the cornerstone of electronic devices. ICs are packaged in an IC package, also called a “semiconductor package” or “chip package,” The IC package includes one or more semiconductor dice (“dies” or “dice”) as an IC(s) that are mounted on and electrically coupled to a package substrate to provide physical support and an electrical interface to the die(s). The die(s) is electrically interfaced to metal interconnects (e.g., metal traces) exposed in a top layer of the package substrate. The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes a bottom, outer metallization layer that includes metal interconnects coupled to external metal interconnects (e.g., ball grid array (BGA) interconnects) to provide an external interface between the die(s) in the IC package. The external metal interconnects can also be coupled (e.g., soldered) to traces in a printed circuit board (PCB) to attach the package to the PCB and interface its die(s) with the circuitry of the PCB.

It is common to include capacitors in IC packages. Capacitors may be included in an IC package to provide a decoupling capacitance for circuits in a die to shunt noise from one electrical circuit (e.g., a power supply circuit) to another electrical circuit (e.g., a powered electrical circuit). Capacitors may also be included in an IC package as part of a filtering circuit for the die. A capacitor can be provided in an IC package as a land-side capacitor (LSC) that is attached to a land-side (opposite the die-side) of the package substrate. A capacitor can also be provided in an IC package as a die-side capacitor (DSC) that is attached to a die-side (opposite the die-side) of the package substrate. A capacitor can also be provided in an IC package as a deep trench capacitor (DTC) that is embedded in the package substrate itself. For example, the capacitor may be embedded in a core substrate of a cored package substrate. In each of these examples, metal interconnects/metal traces within metallization layers of the package substrate provide an electrical connection between a die and the capacitor.

### SUMMARY OF THE DISCLOSURE

Aspects disclosed herein include package substrates with embedded die-side, face-up deep trench capacitor(s) (DTC(s)). Related integrated circuit (IC) packages and fabrication methods are also disclosed. The package substrate is included in an IC package that includes at least one semiconductor die (“die”) electrically coupled to a package substrate to support the die(s) and to provide electrical connections to the die(s). One or more DTCs are embedded in a cavity embedded in the package substrate to provide a capacitor(s) that are coupled to a die(s) in the IC package. In exemplary aspects, to provide a package substrate that minimizes the connection path length between an embedded DTC and a coupled die to reduce impedance and improve capacitor performance, the DTC is disposed face-up in a cavity in the package substrate. By face-up, it is meant that the DTC is disposed in the package substrate such that the external metal interconnects of the DTC (“DTC interconnects”) are oriented face-up towards a die-side outer metallization layer of the IC package and towards a die in a vertical direction when the package substrate is provided in an IC package. Also, to facilitate minimizing the connection path length between the embedded DTC in the package substrate and a coupled die, the DTC can be embedded in the package substrate such that the DTC is disposed underneath the die in a vertical direction when an IC package is formed with the package substrate. The DTC can be embedded in the package substrate such that its DTC interconnects are directly connected to external, die-side interconnects (e.g., metal bumps) disposed in a die-side outer metallization layer of the package substrate. This allows the DTC to be directly connected to the external, die-side interconnects of the package substrate that are in turn connected to the die (e.g., its die interconnects) to further minimize the connection path length between the DTC and a die in an IC package. For example, the DTC interconnects of the DTC can be disposed in a die-side outer metallization layer of the package substrate to be adjacent to the die and. the external, die-side interconnects of the package substrate.

In certain exemplary aspects, the package substrate of the IC package is a cored package substrate that include a core substrate. The DTC is disposed face-up in a cavity formed in a core substrate. The DTC may be disposed in the core substrate such that its DTC interconnects are disposed in the core substrate as a metallization layer configured to be adjacent to the die when the IC package is formed from the cored package substrate. In this manner, the DTC interconnects of the DTC can be directly connected to the external, die-side external interconnects disposed in the die-side outer solder resist layer as an outer metallization layer of the package substrate that are coupled. to the die to minimize connection path length between the DTC and a coupled die. Additional coreless metallization layers may also be included in the package substrate and coupled to the core substrate.

In other exemplary aspects, the package substrate of the IC package is a coreless package substrate. The DTC is disposed face-up in a cavity formed in the coreless metallization layers of the coreless package substrate. The DTC interconnects can be disposed in a die-side outer coreless metallization layer of the package substrate configured to be adjacent to the die when the IC package is formed from the coreless package substrate. In this manner, the DTC interconnects of the DTC can be directly connected to the external, die-side external interconnects of the package substrate that are coupled to the die to minimize connection path length between the DTC and a coupled die.

In yet other exemplary aspects, the package substrate of the IC package is an embedded trace substrate (ETS) that includes a die-side outer ETS metallization layer, wherein the DTC is disposed face-up in a cavity formed in the metallization layers of the package substrate. The DTC interconnects can be disposed in the die-side outer ETS metallization layer of the package substrate that is configured to be adjacent to the die when the IC package is formed from the cored package substrate. In this manner, the DTC interconnects of the DTC can be directly connected to the external, die-side external interconnects of the package substrate that are coupled to the die to minimize connection path length between the DTC and a coupled die.

In this regard, in one exemplary aspect, an IC package is provided. The IC package comprises a die comprising a plurality of die interconnects. The IC package also comprises a package substrate. The package substrate comprises a metallization layer adjacent to the die in a vertical direction, and a plurality of external metal interconnects coupled to the metallization layer. The package substrate also comprises a DTC disposed in the package substrate. The DTC comprises a plurality of DTC interconnects disposed in the metallization layer. Each external metal interconnect among the plurality of external metal interconnect coupled to a die interconnect among the plurality of die interconnects and a DTC interconnect among the plurality of DTC interconnects.

In another exemplary aspect, a method of fabricating an IC package is provided. The method comprises fabricating a package substrate, Fabricating the package substrate comprises forming a metallization layer and forming a plurality of external metal interconnects coupled to the metallization layer. The method of fabricating the IC package also comprises disposing a deep trench capacitor (DTC) comprising a plurality of DTC interconnects in the package substrate such that the plurality of DTC interconnects are disposed in the metallization layer. The method of fabricating the IC package also comprises coupling each DTC interconnect among the plurality of DTC interconnects to an external metal interconnect among the plurality of external metal interconnects. The method of fabricating the IC package also comprises disposing a die adjacent to the metallization layer in a vertical direction, wherein the die comprises a plurality of die interconnects. The method of fabricating the IC package also comprises coupling each of the plurality of die interconnects to an external metal interconnect among the plurality of external metal interconnects,

### BRIEF DESCRIPTION OF THE FIGURES

FIG. 1A is a side view of an exemplary integrated circuit (IC) package that includes a semiconductor die (“die”) mounted on a package substrate, wherein the package substrate includes a deep trench capacitor (DTC) embedded face-up towards the die in a core substrate of the package substrate and disposed underneath the die in a vertical direction, to minimize the connection path length between the DTC and the die;

FIG. 1B is a close-up side view of the IC package in FIG. 1A, illustrating DTC interconnects of the DTC directly coupled to external, die-side interconnects disposed in a die-side outer metallization layer of the package substrate, to minimize the connection path length between the DTC and the die;

FIG. 2 is a side view of another IC package that includes a land-side capacitor (LSC), a die-side capacitor (DSC), and a DTC;

FIG. 3 is a flowchart illustrating an exemplary fabrication process of fabricating an IC package, including but not limited to the IC package in FIGS. 1A and 1B, that includes a DTC embedded face-up towards a die-side outer metallization layer of the package substrate, with DTC interconnects of the DTC coupled to external, die-side interconnects disposed in a die-side outer metallization layer of the package substrate;

FIG. 4A-4C is a flowchart illustrating another exemplary fabrication process of fabricating the package substrate in FIGS. 1A and 1B that includes a DTC embedded face-up towards a die-side outer metallization layer of a cored package substrate, and DTC interconnects of the DTC disposed in a die-side outer solder resist layer of the cored package substrate to couple the DTC interconnects to external, die-side interconnects disposed in the die-side outer metallization layer of the cored package substrate;

FIGS. 5A-5I are exemplary fabrication stages during fabrication of the cored package substrate in FIGS. 4A-4C;

FIG. 6 is a side view of another exemplary IC package that is similar to the IC package in FIGS. 1A and 1B, but with built up additional coreless metallization layers disposed adjacent to the core substrate;

FIG. 7A-7D is a flowchart illustrating another exemplary fabrication process of a fabricating the cored package substrate in FIG. 6;

FIGS. 8A-8I are exemplary fabrication stages during fabrication of the cored package substrate in FIGS. 7A-7D;

FIG. 9 is a side view of another exemplary IC package that includes a DTC embedded in coreless metallization layers of a coreless package substrate and face-up towards a die-side outer metallization layer of the package substrate, wherein DTC interconnects of the DTC are disposed in a die-side outer metallization layer of the coreless package substrate and coupled to external, die-side interconnects disposed in a die-side outer solder resist layer of the coreless package substrate;

FIG. 10A-10C is a flowchart illustrating another exemplary fabrication process of fabricating the coreless package substrate in FIG. 9;

FIGS. 11A-11I are exemplary fabrication stages during fabrication of the coreless package substrate in FIGS. 10A-10C;

FIG. 12 is a side view of another exemplary IC package similar to the IC package in FIG. 9, but with built up additional coreless metallization layers adjacent to the coreless metallization layers of coreless package substrate that embed the DTC;

FIG. 13A-13D is a flowchart illustrating another exemplary fabrication process of fabricating the coreless package substrate in FIG. 12;

FIGS. 14A-14I are exemplary fabrication stages during fabrication of the coreless package substrate in FIGS. 13A-13D;

FIG. 15 is a side view of another exemplary IC package includes a DTC embedded in an embedded trace substrate (ETS) package substrate and face-up towards a die-side outer metallization layer of the package substrate, wherein DTC interconnects of the DTC are disposed in a die-side outer ETS metallization layer of the ETS package substrate and coupled to external, die-side interconnects disposed in a die-side outer solder resist layer of the ETS package substrate;

FIG. 16A-16C is a flowchart illustrating another exemplary fabrication process of fabricating the ETS package substrate in FIG. 15;

FIGS. 17A-17I are exemplary fabrication stages during fabrication of the ETS package substrate in FIGS. 16A-16C;

FIG. 18 is a side view of another exemplary IC package similar to the IC package in FIG. 15, but with the coreless metallization layers of the ETS package substrate that embed the DTC built up with additional coreless metallization layers;

FIG. 19A-19D is a flowchart illustrating another exemplary fabrication process of fabricating the ETS package substrate in FIG. 18;

FIGS. 20A-20J are exemplary fabrication stages during fabrication of the ETS package substrate in FIGS. 19A-19D;

FIG. 21 is a block diagram of an exemplary processor-based system that can include components that can include an IC package that employs a package substrate that includes a DTC embedded face-up towards a die in the package substrate and disposed underneath the die in a vertical direction, to minimize the connection path length between the DTC and the die, including but not limited to the package substrates in FIGS. 1A-1B, 6, 9, 12, 15, and 18, and according to, but not limited to, any of the exemplary fabrication processes in FIGS. 4A-5I, 7A-81, 10A-11I, 13A-14I, 16A-17I, and 19A-20J; and

FIG. 22 is a block diagram of an exemplary wireless communications device that includes radio-frequency (RF) components that can include an IC package that employs a package substrate that includes a DTC embedded face-up towards a die in the package substrate and disposed underneath the die in a vertical direction, to minimize the connection path length between the DTC and the die, including but not limited to the package substrates in FIGS. 1A-1B, 6, 9, 12, 15, and 18, and according to, but not limited to, any of the exemplary fabrication processes in FIGS. 4A-5I, 7A-8I, 10A-11I, 13A-14I, 16A-17I, and 19A-20J.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include package substrates with embedded die-side, face-up deep trench capacitor(s) (DTC(s)). Related integrated circuit (IC) packages and fabrication methods are also disclosed. The package substrate is included in an IC package that includes at least one semiconductor die (“die”) electrically coupled to a package substrate to support the die(s) and to provide electrical connections to the die(s), One or more DTCs are embedded in a cavity embedded in the package substrate to provide a capacitor(s) that are coupled to a die(s) in the IC package. In exemplary aspects, to provide a package substrate that minimizes the connection path length between an embedded DTC and a coupled die to reduce impedance and improve capacitor performance, the DTC is disposed face-up in a cavity in the package substrate. By face-up, it is meant that the DTC is disposed in the package substrate such that the external metal interconnects of the DTC (“DTC interconnects”) are oriented face-up towards a die-side outer metallization layer of the IC package and towards a die in a vertical direction when the package substrate is provided in an IC package. Also, to facilitate minimizing the connection path length between the embedded DTC in the package substrate and a coupled die, the DTC can be embedded in the package substrate such that the DTC is disposed underneath the die in a vertical direction when an IC package is formed with the package substrate. The DTC can be embedded in the package substrate such that its DTC interconnects of the DTC can be directly coupled to external, die-side interconnects (e.g., metal bumps) disposed in a die-side outer metallization layer of the package substrate. This allows the DTC to be directly connected to the external, die-side interconnects of the package substrate that are in turn connected to the die (e.g., its die interconnects) to further minimize the connection path length between the DTC and a die in an IC package. For example, the DTC interconnects of the DTC can be disposed in a die-side outer layer or die-side outer metallization layer of the package substrate to be adjacent to external, die-side interconnects of the package substrate.

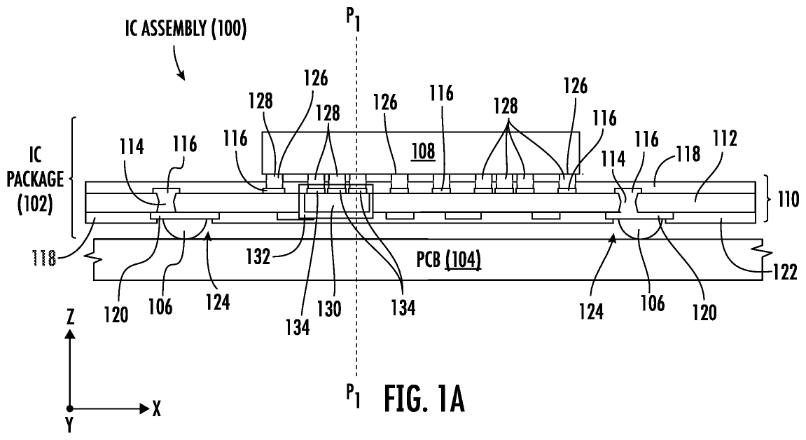

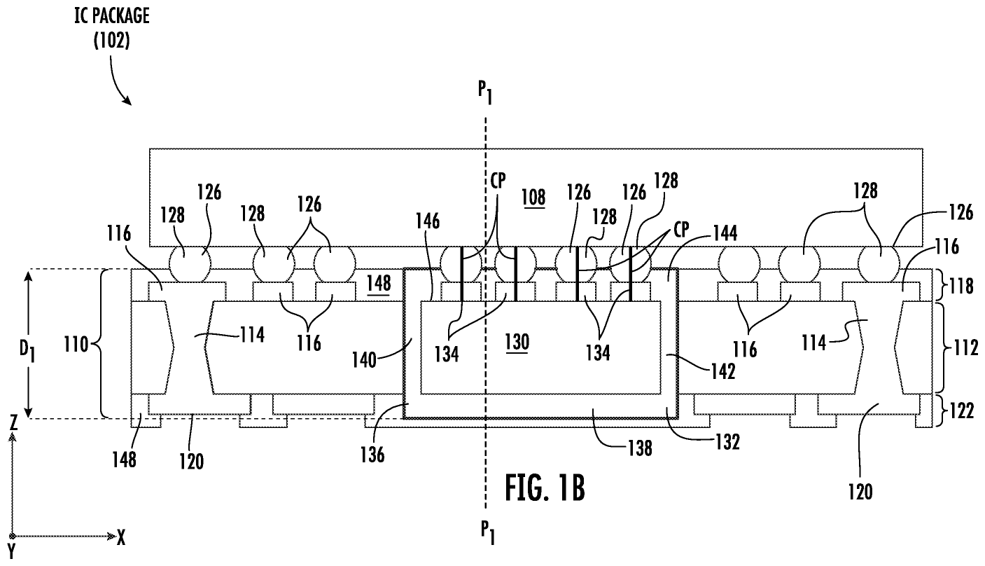

In this regard, FIGS. 1A and 1B illustrate schematic side views of a cross-section of an IC assembly 100 that includes an IC package 102 that is mounted to a printed circuit board (PCB) 104 using external interconnects 106, such as solder balls. FIG. 1B is a close-up side view of the IC package 102 in FIG. 1A. As shown in FIG. 1A, the IC package 102 includes a semiconductor die 108 (also referred to as “IC die 108” or “die 108”) that is mounted to a package substrate 110, such as by a die-to-die bonding and/or underfill adhesive. The external interconnects 106 are coupled to metal interconnections (e.g., metal traces, metal lines, vertical interconnect accesses (vias)) in the package substrate 110 to provide an electrical interface to the die 108 when the IC package 102 is mounted to the PCB 104. In this example, the package substrate 110 includes a core substrate 112 as a metallization layer and also referred to as a “metallization layer 112.” The core substrate 112 includes metal posts 114 (as metal interconnects) disposed in a dielectric insulating material that is thicker and stiffer to reduce or avoid warpage and damage to the IC package 102. The metal posts 114 provide signal routing paths in the core substrate 112. The metal posts 114 are disposed in a dielectric material of the core substrate 112 and are coupled between external metal interconnects 116 disposed in a die-side outer metallization layer 118, that is a solder resist layer in this example. The die-side outer metallization layer 118 is named a “die-side” layer, because a die-side outer metallization layer 118 is adjacent to the die 108. Metal interconnects 120 are disposed in a lower, outer metallization layer 122, which is also referred to as a solder resist layer 122 since the outer metallization layer 122 is a solder resist layer in this example. The core substrate 112 is disposed between the upper and lower solder resist layers 118, 122 in a vertical direction (Z-axis direction). The metal posts 114 provide signal routing paths between the respective coupled metal interconnects 116, 120 and to the external interconnects 106 to provide an external interface to the die 108. The external interconnects 106 are formed in openings 124 in the lower solder resist layer 122 and coupled to the metal posts 114 of the core substrate 112.

With continuing reference to FIG. 1A, certain of the metal interconnects 116 of the outer metallization layer 118 of the package substrate 110 are disposed underneath the die 108 in a vertical direction (Z-axis direction) and electrically coupled to the die 108 to provide an electrical connection between the die 108 and the package substrate 110. In this regard, die interconnects 126 of the die 108 are disposed above and coupled to respective external metal interconnects 128 in the die-side outer metallization layer 118 of the package substrate 110. The external metal interconnects 128 are formed in the solder resist layer as the die-side outer metallization layer 118 of the package substrate 110. The external metal interconnects 128 may be solder balls or ball grid array (BGA) interconnects as examples. The external metal interconnects 128 are coupled to respective metal interconnects 116 disposed the outer metallization layer 118 to couple the die 108 to the package substrate 110.

Also, as shown in FIG. 1A, a deep trench capacitor (DTC) 130 is provided in the package substrate 110 and coupled to the die 108 to provide a capacitor that is coupled to the die 108. The DTC 130 can be embedded in the package substrate 110 of the IC package 102 to provide a decoupling capacitance to shunt noise from one electrical circuit (e.g., a power supply circuit) to another electrical circuit (e.g., a powered electrical circuit) in the die 108. The DTC 130 could also be used as part of a filtering component for a filtering circuit for the die 108. The DTC 130 must be disposed in the package substrate 110 in a manner that the DTC 130 is electrically coupled to the die 108. It is desired to minimize the connection path length between the die 108 and the coupled DTC 130, because inductance in the connection path increases as a function of increased connection path length. An increased inductance can result in a loss of performance of the DTC 130.

Thus, as shown in FIG. 1A, to provide a design for the package substrate 110 that minimizes the connection path length between the DTC 130 and the die 108 to reduce impedance and improve capacitor performance of the DTC 130, the DTC 130 is disposed face-up in a vertical direction (Z-axis direction) in a cavity 132 in the package substrate 110. As discussed in more detail below, the cavity 132 is bounded by a dielectric material that insulates the DTC 130 from surrounding metal components in the package substrate 110. By face-up, it is meant that the DTC 130 is disposed in the package substrate 110 such that external metal interconnects 134 of the DTC 130 (referred to herein as the “DTC interconnects 134”) are oriented face-up towards the die-side outer metallization layer 118 of the package substrate 110 and the die 108 of the IC package 102 in a vertical direction (Z-axis direction). DTC interconnects 134 are metal terminals, wires, pins or other metal conductors that provide an electrical interface to the capacitive element(s) in the DTC 130. By orienting the DTC interconnects 134 to be face-up towards to die-side outer metallization layer 118 and the die 108 in the vertical direction (Z-axis direction), the connection path length between the die 108 and the DTC 130 is reduced. This is because the connection paths do not have to be routed lower below the cavity 132 in a vertical direction (Z-axis direction) to reach the DTC interconnects 134 to establish a connection with the DTC 130.

Also in this example, as shown in FIG. 1A and the close-up side view of the package substrate 110 in FIG. 1B, to further facilitate minimizing the connection path length between the embedded DTC 130 in the package substrate 110 and the die 108, the DTC 130 is embedded in the package substrate 110 such that the DTC 130 is disposed underneath the die 108 in a vertical direction (Z-axis direction). The DTC 130 and the die 108 share a common vertical plane Pi in a vertical direction (X- and Z-axes directions). In this example, the DTC 130 is also embedded in the core substrate 112 such that the DTC interconnects 134 of the DTC 130 are disposed in the die-side outer metallization layer 118 of the package substrate 110 directly below respective external metal interconnects 128 in the die-side outer metallization layer 118 in the vertical direction (Z-axis direction). In this manner, the DTC interconnects 134 can be directly connected to the external metal interconnects 128, which are connected to die interconnects 126 in this example, to provide an electrical connection between the DTC 130 and the die 108. By disposing the DTC 130 in the package substrate 110 such that the DTC interconnects 134 are disposed in the die-side outer metallization layer 118 in this example, the connection path length between the DTC 130 and the die 108, through the external metal interconnects 128 and the die interconnects 126, is minimized to minimize the inductance of the connection. Additional routing in the horizontal direction (X- and Y-axes directions) is not required to connect the DTC 130 to the die 108 in this example.

FIG. 1B is a close-up side view of the package substrate 110 in the IC package 102 in FIG. 1A to further illustrate the embedding of the DTC 130 face-up in the package substrate 110 to minimize the connection path length between the die 108 and the DTC 130. As shown in FIG. 1B, in this example, the DTC 130 is disposed in a cavity 132 that is formed in the core substrate 112 of the package substrate 110. The cavity 132 is bounded by a dielectric material 136 on a bottom side 138, sides 140, 142, and a top side 144 to insulate the DTC 130 from the metal posts 114 in the core substrate 112 and other metal components in the package substrate 110. The DTC 130 has a first, upper face 146 disposed in the core substrate 112. The DTC interconnects 134 are exposed from the first, upper face 146 of the DTC 130 such that the .DTC interconnects 134 are disposed in the die-side outer metallization layer 118 of the package substrate 110. In this example, the portion of the die-side outer metallization layer 118 that is disposed above the upper face 146 of the DTC 130 forms the top side 144 of the cavity 132 that bounds the cavity 132. In this example, the dielectric material 136 that forms the bottom side 138, and sides 140, 142 is the same dielectric material 148 that the die-side outer metallization layer 118 and outer metallization layer 122 are made from, which are solder resist layers in this example. As will be discussed in more detail below, when fabricating the package substrate 110, it may be efficient to dispose the dielectric material 136 in the package substrate 110 that forms the cavity 132 and as part of the same fabrication steps that are used to form the outer metallization layer 122 and/or a metallization layer in the package substrate 110, such as the core substrate 112.

As discussed above and shown in. FIG. 1B, in this example, the DTC 130 is embedded in the core substrate 112 such that the DTC interconnects 134 of the DTC 130 are disposed in the die-side outer metallization layer 118 of the package substrate 110 directly below respective external metal interconnects 128 in the die-side outer metallization layer 118 in the vertical direction (Z-axis direction). In this manner, the DTC interconnects 134 can be directly connected to the external metal interconnects 128, which are connected to die interconnects 126 in this example, to provide an electrical connection between the DTC 130 and the die 108. This is shown by the connection paths CP labeled in FIG. 1B between the die 108 and the DTC 130. By disposing the DTC 130 in the package substrate 110 such that the DTC interconnects 134 are disposed in the die-side outer metallization layer 118 in this example, the connection path length between the DTC 130 and the die 108, through the external metal interconnects 128 and the die interconnects 126, is minimized to minimize the inductance of the connection. Additional routing in the horizontal direction (X- and Y-axes directions) is not required to provide the connection paths CP between the DTC 130 to the die 108 in this example.

With continuing reference to FIG. 1B, the cavity 132 in this example extends in a vertical direction V-axis direction) through the die-side outer metallization layer 118, the core substrate 112, and the outer metallization layer 122. The cavity 132 should be formed in the package substrate 110 of a sufficient depth Di to support the volume needed to embed the DTC 130 of a desired size and capacity in the package substrate 110. As shown in. FIG. 1B, the metal posts 114 can also be coupled to die 108 through die interconnects 126 coupled to external metal interconnects 128 in the die-side outer metallization layer 118, which are coupled to metal interconnects 116 in the die-side outer metallization layer 118. These connections provide signal routing from the die 108 in the package substrate 110 and to the external metal interconnects 106 (see FIG. 1A) to provide an external interface to the die 108.

FIG. 2 is a side view of another IC package 200 that includes a land-side capacitor (LSC) 202, a die-side capacitor (DSC) 204, and a DTC 206 that does not minimize the connection path lengths like the IC package 102 in FIGS. 1A and 1B. As shown in FIG. 2, the IC package 200 includes a die 208 coupled to a package substrate 210. The LSC 202 is mounted on a bottom surface 212 of the package substrate 210 and thus is disposed, at a minimum, a distance away from the die 208 that includes the distance of the entire width W₁ of the package substrate 210 in the vertical direction (Z-axis direction). This results in a longer connection path length 214 that can degrade performance of the LSC 202, unlike the face-up embedding of the DTC 130 in the IC package 102 in FIGS. 1A and 1B wherein the DTC interconnects 134 are disposed in. the die-side outer metallization layer 118 of the package substrate directly beneath die interconnects 126 of the die 208. The DSC 204 is mounted on a top surface 216 of the package substrate 210. Thus, to not interfere with the die 208, the DSC 204 is mounted to the package substrate 210 in an area that is laterally displaced from the die 208 in the horizontal direction (X- and Y-axes directions). Thus, the DSC 204 is disposed a distance away from the die 208that, at a minimum, includes the laterally displacement distance between the DSC 204 and the die 208. This results in a longer connection path length 218 that can degrade performance of the DSC 204, unlike the face-up embedding of the DTC 130 in the IC package 102 in FIGS. 1A and 1B wherein the DTC interconnects 134 are disposed in the die-side outer metallization layer 118 of the package substrate directly beneath die interconnects 126 of the die 108. Also, the DTC 206 is embedded in the package substrate 210 of the IC package 200 in FIG. 2, but the DTC 206 is also laterally displaced from the die 208 in the horizontal direction (X- and Y-axes directions). The DTC 206 is not disposed underneath the die 206 in a vertical direction (Z-axis direction). Further, the DTC 206 is not in the package substrate 210 such that it can be directly connected to interconnects in a top, outer layer 220 of the package substrate 210. This also results in a longer connection path length 222 that can degrade performance of the DTC 206, unlike the face-up embedding of the DTC 130 in the IC package 102 in FIGS. 1A and 1B wherein the DTC interconnects 134 are disposed in the die-side outer metallization layer 118 of the package substrate directly beneath die interconnects 126 of the die 108.

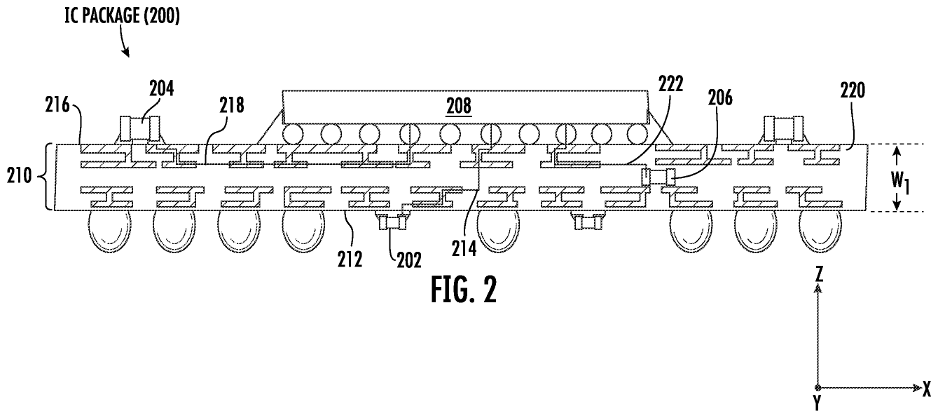

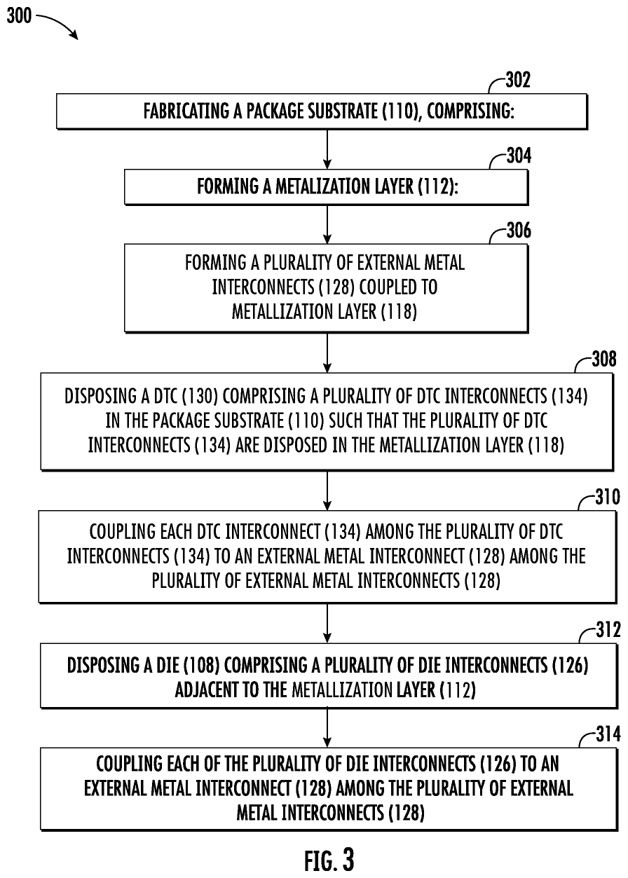

Fabrication processes can be employed to fabricate a package substrate for an IC package that includes a DTC embedded face-up towards a die-side outer metallization layer of the package substrate, with DTC interconnects of the DTC connected to external, die-side interconnects disposed in a die-side outer metallization layer of the package substrate, to minimize the connection path length between the DTC and the die, including but not limited to the package substrate 110 in FIGS. 1A and 1B. In this regard, FIG. 3 is a flowchart illustrating an exemplary fabrication process 300 of fabricating a package substrate that includes a DTC embedded face-up towards a die-side outer metallization layer of the package substrate, with DTC interconnects of the DTC connected to external, die-side interconnects disposed in a die-side outer metallization layer of the package substrate, to minimize the connection path length between the DTC and the die, including but not limited to the package substrate 102 in. FIGS. 1A and 1B. The fabrication process 300 in FIG. 3 is discussed with regard to the package substrate 110 in FIGS. 1A and 1B, but note that the fabrication process 300 is not limited to fabricating a package substrate like the package substrate 110 in FIGS. 1A and 1B.

In this regard, as shown in FIG. 3, a first step of the fabrication process 300 in this example is fabricating a package substrate 110 (block 302 in FIG. 3). The process of fabricating the package substrate 110 includes forming the metallization layer 112, which is the core substrate 112 in the example of the package substrate 110 in FIGS. 1A and 1B (block 304 in FIG. 3). A next step of fabricating the package substrate 110 includes forming the plurality of external metal interconnects 128 coupled to the package substrate 110 (block 306 in FIG. 3). In this example, the external metal interconnects 128 are formed in the die-side outer metallization layer 118 which is a solder resist layer in this example in FIGS. 1A and 1B. This step is performed to setup further steps of attaching the die 108 to the package substrate 110 so that the die interconnects 126 of the die 108 can be coupled to the external metal interconnects 128 that are coupled to the DTC interconnects 134 of the DTC 130. A next step of fabricating the package substrate 110 includes disposing the DTC 130 comprising the plurality of DTC interconnects 134 in the package substrate 110 such that the plurality of DTC interconnects 134 are disposed in the outer metallization layer 118 (block 308 in FIG. 3). A next step of fabricating the package substrate 110 includes coupling each DTC interconnect 134 of the DTC 130 to a respective external metal interconnect 128 to provide for the DTC interconnects 134 to be able to be coupled to the die 108 when attached to the package substrate 110 (block 310 in FIG. 3). A next step of fabricating the package substrate 110 includes disposing the die 108 adjacent to the metallization layer 112 (block 312 in FIG. 3). A next step of fabricating the package substrate 110 includes coupling each of the plurality of die interconnects 126 of the die 108 to an external metal interconnect 128 among the plurality of external metal interconnects 128 (block 314 in FIG. 3).

As part of coupling the die interconnects 126 to the external metal interconnect 128 in the package substrate 110, the die interconnects 126 are coupled to the DTC 130 being embedded in the package substrate 110 with the DTC interconnects 134 disposed in the metallization layer 112 adjacent to the die 108. In this manner, the DTC interconnects 134 are disposed face-up towards the die-side outer metallization layer 118 and die 108 and coupled to the external metal interconnects 128 in the die-side outer metallization layer 118.

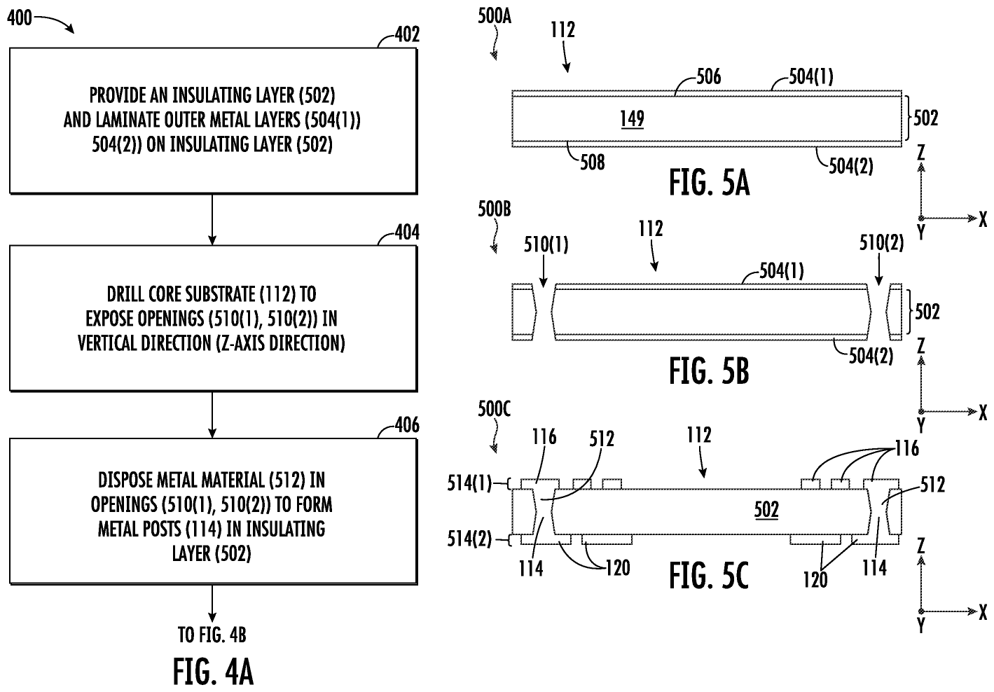

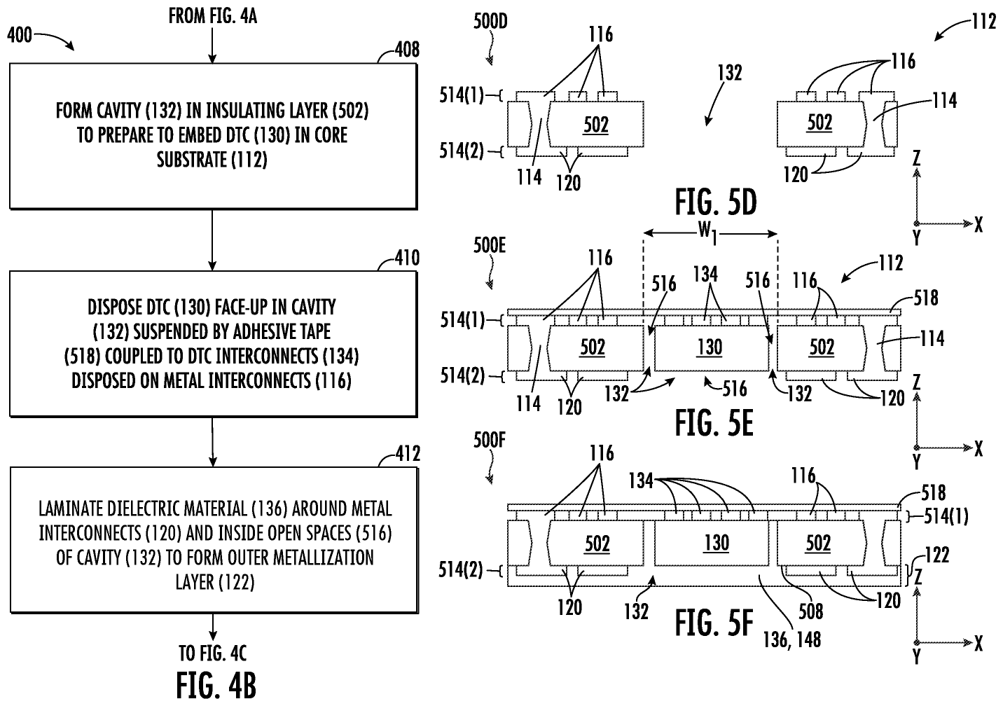

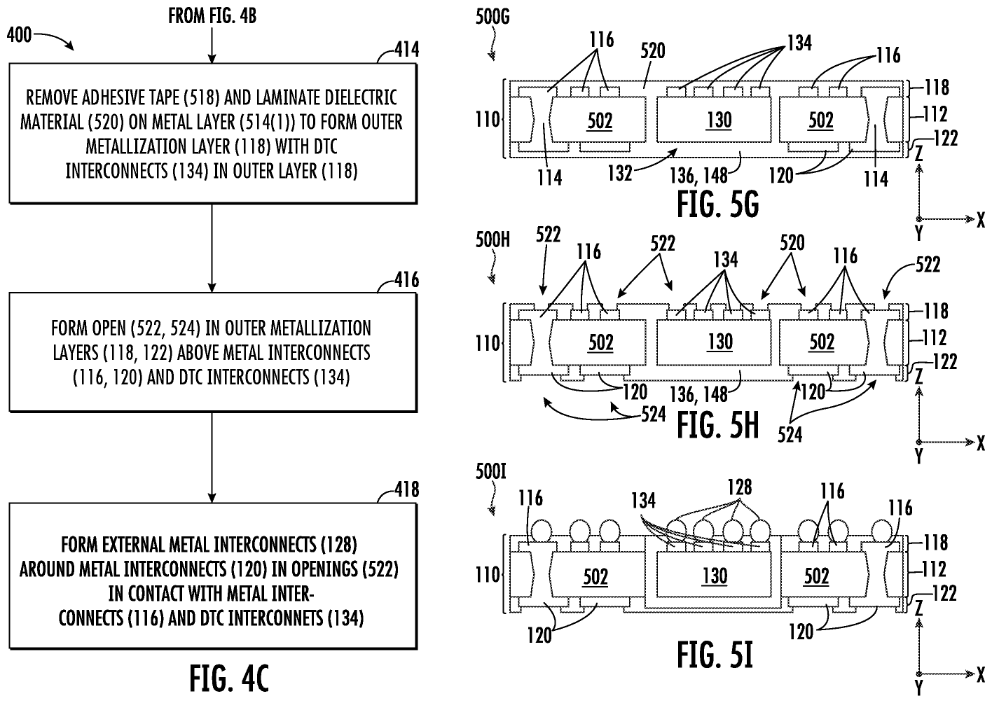

Other fabrication processes can also be employed to fabricate a package substrate for an IC package that includes a DTC embedded face-up towards a die-side outer metallization layer of the package substrate, with DTC interconnects of the DTC connected to external, die-side interconnects disposed in a die-side outer metallization layer of the package substrate, to minimize the connection path length between the DTC and the die, including but not limited to the package substrate 110 FIGS. 1A and 1B. In this regard, FIGS. 4A-4C is a flowchart illustrating another exemplary fabrication process 400 of fabricating the package substrate 110 in FIGS. 1A and 1B. FIGS. 5A-5I are exemplary fabrication stages 500A-5001 during fabrication of the package substrate 110 according to the fabrication process 400 in FIGS. 4A-4C. The fabrication process 400 in FIGS. 4A-4C, and as shown in the fabrication stages 500A-5001 in FIGS. 5A-5I, will now be discussed in reference to the package substrate 110 in FIGS. 1A and 1B as an example.

In this regard, as shown in the exemplary fabrication stage 500A in FIG. 5A, an insulating layer 502 of the dielectric material 149 for the core substrate 112 is provided (block 402 in FIG. 4A). Outer metal layers 504(1), 504(2) are disposed on the top and bottom sides 506, 508 of the insulating layer 502 (block 402 in FIG. 4A). For example, the dielectric material 149 of the insulating layer 502 may be an organic resin material or inorganic filter material. Also as an example, the outer metal layers 504(1), 504(2) disposed on the top and bottom sides 506, 508 of the insulating layer 502 may be copper clad laminate (CCL) layers such that the core substrate is a. CCL substrate. The top side 506 of the insulating layer 502 will eventually be on the die-side of an IC package when the package substrate is fully fabricated and used to fabricate an IC package.

Then, as shown in the exemplary fabrication stage 50013 in FIG. 5B, the core substrate 112 is drilled, such as by laser drilling, to expose openings 510(1), 510(2) in a vertical direction (Z-axis direction) through the core substrate 112 to prepare for metal posts 114 to be formed and in electrical contact with the outer metal layers 504(1), 504(2) (block 404 in FIG. 4A). Then, as shown in the exemplary fabrication stage 500C in FIG. 5C, a metal material 512 is disposed in the openings 510(1), 510(2) to form the metal posts 114 in the insulating layer 502 of the core substrate 112 (block 406 in FIG. 4A). The metal material 512 is disposed over the surface of the outer metal layers 504(1), 504(2) acting as a seed layer, which is then patterned, such as through a lithography and etching process, to form respective metal interconnects 116, 120 in respective metal layers 514(1), 514(2). As discussed above with respect to FIGS. 1A and 1B, the metal interconnects 116 are coupled to external metal interconnects 128 that will be formed in a die-side outer metallization layer 118 formed on the metal layer 514(1) to provide connection to a coupled die 108.

As shown in the exemplary fabrication stage 500D in FIG. 5D, to prepare to embed the DTC 130 in the core substrate 112, the cavity 132 is formed in the insulating layer 502 (block 408 in FIG. 4B). The cavity 132 can be formed in the insulating layer 502 by lithography patterning and etching or by drilling as examples. The width W₁ of the cavity 132 should be formed so that the DTC 130 can be disposed width-wise in the horizontal direction (X- and Y-axes directions) inside the cavity 132 and with a tolerance of open spaces 516 (as shown in exemplary fabrication stage 500E in FIG. 5E) on the sides of the DTC 130 so that a dielectric material can be disposed inside the open spaces 516 to insulate the DTC 130 in the core substrate 112. The DTC 130 was fabricated as a separate component in a separate process in this example. As shown in the exemplary fabrication stage 500E in FIG. 5E, the DTC 130 is disposed in the cavity 132 formed in the insulating layer 502 to prepare for embedding the DTC 130 in the core substrate 112 (block 410 in FIG. 4B). The DTC 130 is suspended inside the cavity 132 in this example so that a dielectric material can then be disposed around the open spaces 516 around the DTC 130 to insulate the DTC 130. In this regard, as shown in the exemplary fabrication stage 500E in FIG. 5E, the DTC 130, and more specifically its DTC interconnects 134, are coupled to an adhesive tape 518 in this example that is then also disposed in contact with the metal interconnects 116 in the metal layer 514(1). This suspends the DTC 130 in the cavity 132 in a face-up direction towards the metal layer 514(1), which will be the die-side metal layer in the eventually formed IC package. The adhesive tape 518 being coupled to the metal interconnects 116 supports and suspends the DTC 130 inside the cavity 132. The DTC interconnects 134 being coupled to the adhesive tape 518, and the adhesive tape 518 being disposed over the metal interconnects 116 also provides for the DTC interconnects 134 to be disposed in the same metal layer 514(1) as the metal interconnects 116 so as to be disposed in the die-side outer metallization layer 118 when later formed.

Then, as shown in the exemplary fabrication stage 500F in FIG. 5F, while the DTC 130 is suspended face-up in the core substrate 112, the outer metallization layer 122 as a solder resist layer in this example is formed on the bottom side 508 of the insulating layer 502 by laminating a dielectric material 136 around the metal interconnects 120 and inside the open spaces 516 of the cavity 132 adjacent to the DTC 130 (block 412 in FIG. 4B). This secures the DTC 130 embedded within the insulating layer 502 of the core substrate 112. Also, using this fabrication process 400, the dielectric material 148 that is used to form the outer metallization layer 122 is also the same dielectric material 136 that bounds the cavity 132 and is disposed around the DTC 130 to insulate the DTC 130. Thus, using this fabrication process 400, the arc 130 can be insulated in the cavity 132 using the same fabricating process that is used to form the outer metallization layer 122 of the package substrate 110. Then, as shown in the exemplary fabrication stage 500G in FIG. 5G, since the DTC 130 is secured inside the cavity 132 by the dielectric material 148 of the outer metallization layer 122 as dielectric material 136, the adhesive tape 518 shown in exemplary fabrication stage 500F in FIG. 5F can be removed (block 414 in FIG. 4C). This is to prepare the die-side outer metallization layer 118 to be formed over metal layer 514(1) that includes the metal interconnects 116 and the DTC interconnects 134 as shown in the exemplary fabrication stage 500G in FIG. 5G as part of the formed package substrate 110 (block 414 in FIG. 4C). The die-side outer metallization layer 118 is formed by laminating a dielectric material 520 on the metal layer 514(1) on the metal interconnects 116 and the DTC interconnects 134.

Then, as shown in the exemplary fabrication stage 500H in FIG. 5H, openings 522, 524 are formed in the respective outer metallization layers 118, 122 above the metal interconnects 116, 120, and DTC interconnects 134 of the package substrate 110 to expose the metal interconnects 116, 120, and DTC interconnects 134 from the outer metallization layers 118, 122 to be coupled as part of forming an IC package (block 416 in FIG. 4C). Then, as shown in the exemplary fabrication stage 500I in FIG. 5I, a bumping process is performed to form the external metal interconnects in the openings 522, 524 of the respective outer metallization layers 118, 122 of the package substrate 110 (block 418 in FIG. 4C). The bumping process forms the external metal interconnects 128 that are coupled to the respective metal interconnects 116 and DTC interconnects 134 in the outer metallization layer 118 as shown in FIG. 5I. The external metal interconnects 128 can be formed as solder balls, solder joints, metal posts, or other interconnects. As discussed above with reference to FIGS. 1A and 1B, the arc interconnects 134 being disposed face-up towards the die-side outer metallization layer 118 and disposed in the metal layer 514(1) allows the DTC interconnects 134 to be directly coupled to the formed external metal interconnects 128 to provide a connection to die interconnects 126 of a die 108 that is disposed adjacent to the outer metallization layer 118 of the package substrate 110 when the IC package 102 in FIGS. 1A and 1B is formed. This is to minimize the connection path length between the die 108 and the DTC 130.

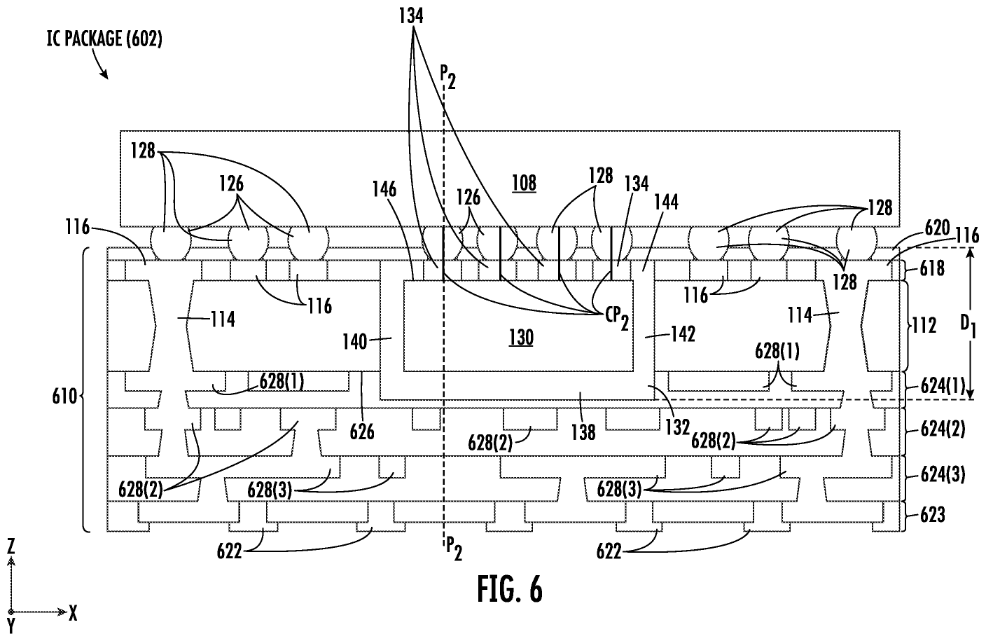

Other designs of package substrates can be provided for use an IC package, wherein the package substrate includes a DTC embedded face-up towards a die-side outer metallization layer of the package substrate, with DTC interconnects of the DTC connected to external, die-side interconnects disposed in a die-side outer metallization layer of the package substrate, to minimize the connection path length between the DTC and the die. In this regard, FIG. 6 is a side view of another exemplary IC package 602 that includes a package substrate 610 that is similar to the package substrate 110 in FIGS. 1A and 1B. However, as discussed in more detail below, the package substrate 610 in FIG. 6 has the core substrate 112 additionally built up with additional careless metallization layers to form an asymmetric package substrate 610. Common elements between the IC package 102 and package substrate 110 in FIGS. 1A and 1B and the IC package 602 and package substrate 610 in FIG. 6 are shown with common element numbers. The previous discussion of such common elements is applicable to the package substrate 610 in FIG. 6.

In this regard, with reference to FIG. 6, the metal interconnects 116 and the DTC interconnects 134 of the arc 130 are disposed in a metallization layer 618 that is die-side, outer metallization layer of the package substrate 610. The metallization layer 618 is formed on the core substrate 112 and is similar to the outer metallization layer 118 of the package substrate 110 in FIGS. 1A and 1B. However, the metallization layer 618 is not a solder resist layer in this example. A separate solder resist layer 620 is disposed on the metallization layer 618 as a die-side outer metallization layer 620. The external metal interconnects 128 are disposed through the solder resist layer 620 adjacent to the metallization layer 618 and in contact with the metal interconnects 116 and DTC interconnects 134 in the metallization layer 618 to couple the die 108 to the package substrate 610 and to the DTC 130. The DTC 130 and the die 108 share a common vertical plane P₂ in a vertical direction (X- and Z-axes directions). The DTC 130 is embedded in the core substrate 112 such that the DTC interconnects 134 of the DTC 130 are disposed in the metallization layer 618 of the package substrate 610 directly below respective external metal interconnects 128 in the die-side outer metallization layer 620 in the vertical direction (Z-axis direction). In this manner, the DTC interconnects 134 can be directly connected to the external metal interconnects 128, which are connected to die interconnects 126, to provide an electrical connection between the DTC 130 and the die 108. This is shown by the connection paths CP₂ labeled in FIG. 6 between the die 108 and the arc 130. By disposing the DTC 130 in the package substrate 610 such that the DTC interconnects 134 are disposed in the metallization layer 618 in this example, the connection path length between the DTC 130 and the die 108, through the external metal interconnects 128 and the die interconnects 126, is minimized to minimize the inductance of the connection. Additional routing in the horizontal direction (X- and Y-axes directions) is not required to provide the connection paths CP₂ between the DTC 130 to the die 108 in this example.

Also, as shown in FIG. 6, the package substrate 610 includes additional, second coreless metallization layers 624(1)-624(3) that are build-up on the bottom surface 626 of the core substrate 112. The core substrate 112 is disposed between the metallization layer 618 and the second coreless metallization layers 624(1)-624(3). Each of the coreless metallization layers 624(1)-624(3) includes respective metal interconnects 628(1)-628(3) (e.g., metal traces, metal lines, metal posts) that can be connected to adjacent metal interconnects 628(1)-628(3) in adjacent coreless metallization layers 624(1)-624(3) to provide signal routing paths in the package substrate 610. Certain metal interconnects 628(1) in the coreless metallization layer 624(1) are connected to the metal posts 114 in the core substrate 112 to provide a signal routing path through the core substrate 112 to the die 108. Certain metal interconnects 628(3) in the coreless metallization layer 624(3) are connected to the metal interconnects 622 in a bottom, outer solder resist layer 623 to provide a connection between the package substrate 610 and external metal interconnects (e.g., solder balls) formed in contact with the metal interconnects 622.

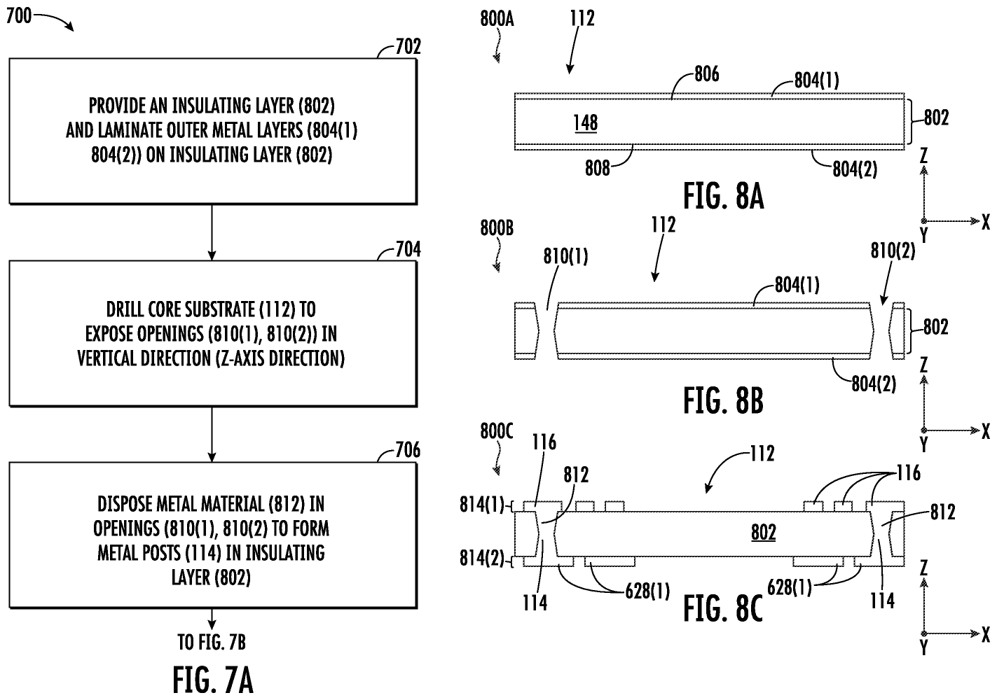

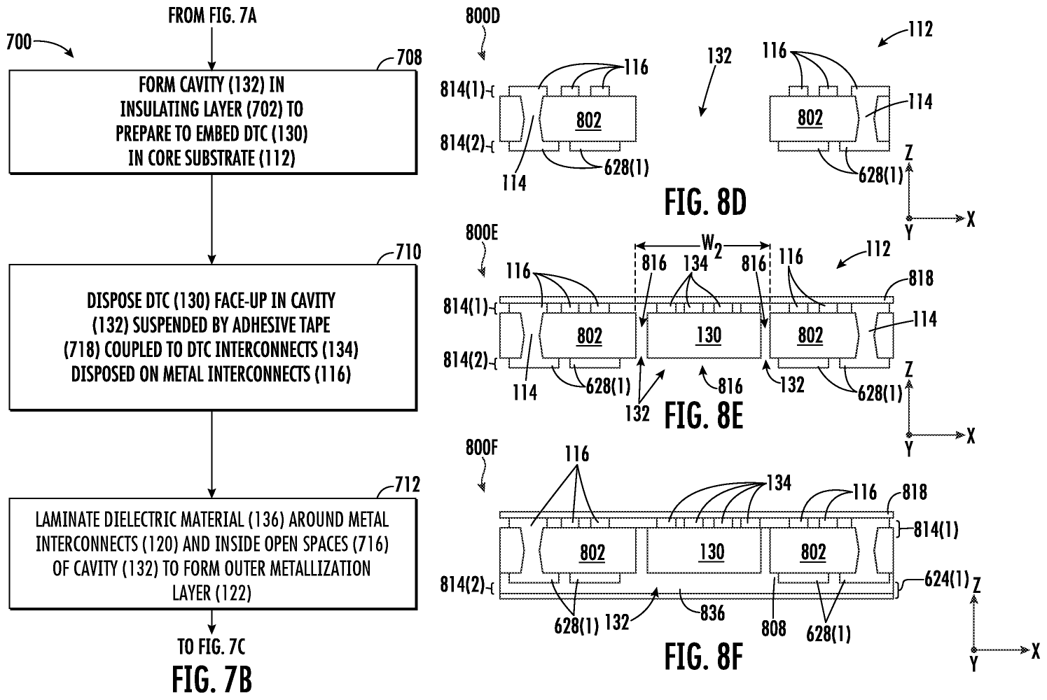

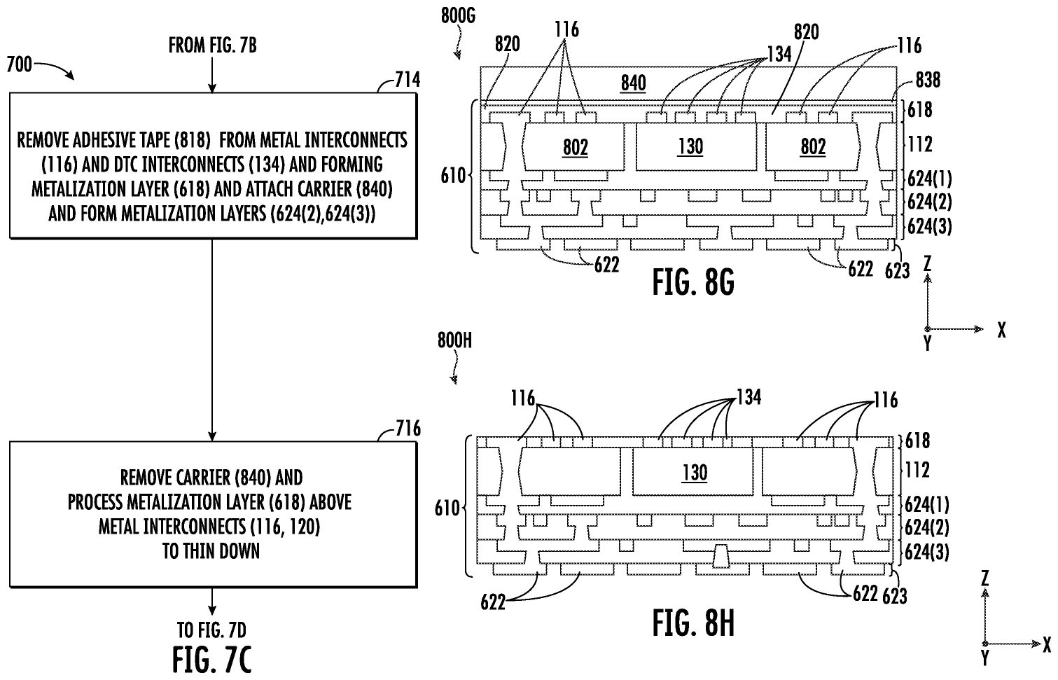

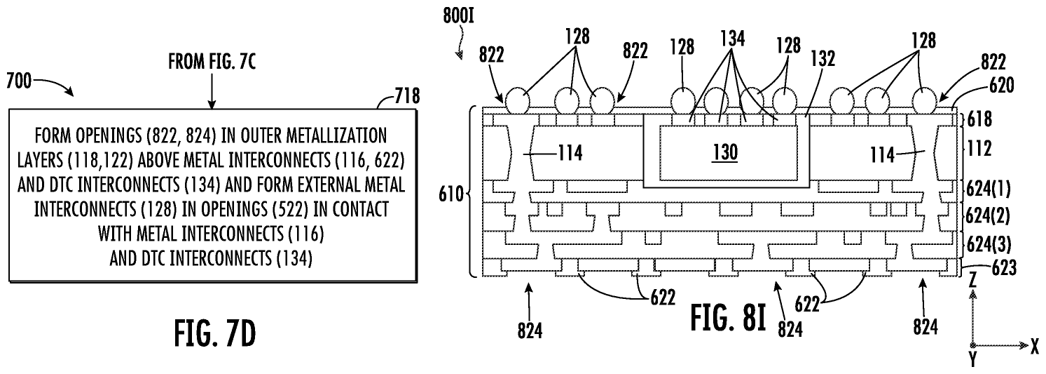

FIGS. 7A-7D is a flowchart illustrating another exemplary fabrication process 700 of fabricating the package substrate 610 in FIG. 6. FIGS. 8A-8I are exemplary fabrication stages 800A-8001 during fabrication of the package substrate 610 according to the fabrication process 7(K) in FIGS. 7A-7D. The fabrication process 700 in FIGS. 7A-7D, and as shown in the exemplary fabrication stages 800A-8001 in FIGS. 8A-8I, will now be discussed in reference to the package substrate 610 in FIG. 6 as an example.

In this regard, as shown in the exemplary fabrication stage 800A in FIG. 8A, an insulating layer 802 of the dielectric material 148 for the core substrate 112 is provided (block 702 in FIG. 7A). Outer metal layers 804(1), 804(2) are disposed on the top and bottom sides 806, 808 of the insulating layer 802 (block 702 in FIG. 7A). For example, the dielectric material 148 of the insulating layer 802 may be an organic resin material or inorganic filter material. Also as an example, the outer metal layers 804(1), 804(2) disposed on the top and bottom sides 806, 808 of the insulating layer 802 may be copper clad laminate (CCL) layers such that the core substrate is a CCL substrate. The top side 806 of the insulating layer 802 will eventually be on the die-side of an IC package when the package substrate is hilly fabricated and used to fabricate an IC package. The outer metal layer 804(1). Then, as shown in the exemplary fabrication stage 800B in FIG. 8B, the core substrate 112 is drilled, such as by laser drilling, to expose openings 810(1), 810(2) in a vertical direction (Z-axis direction) through the core substrate 112 to prepare for metal posts 114 to be formed and in electrical contact with the outer metal layers 804(1), 804(2) (block 704 in FIG. 7A). Then, as shown in the exemplary fabrication. stage 800C in FIG. 8C, a metal material 812 is disposed in the openings 810(1), 810(2) to form the metal posts 114 in the insulating layer 802 of the core substrate 112 (block 706 in FIG. 7A). The metal material 812 is disposed over the surface of the outer metal layers 804(1), 804(2) acting as a seed layer, which is then patterned, such as through a. lithography and etching process, to form respective metal interconnects 116, 628(1) in respective metal layers 814(1), 814(2). As discussed above with respect to FIG. 6, the metal interconnects 116 are coupled to external metal interconnects 128 that will be formed in a die-side outer metallization layer 118 formed on the metal layer 814(1) to provide connection to a coupled die 108.

As shown in the exemplary fabrication stage 800D in FIG. 8.D, to prepare to embed the DTC 130 in the core substrate 112, the cavity 132 is formed in the insulating layer 802 (block 708 in FIG. 7B). The cavity 132 can be formed in the insulating layer 802 by lithography patterning and etching or by drilling as examples. The width W2 of the cavity 132 should be formed so that the DTC 130 can be disposed width-wise in the horizontal direction (X- and Y-axes directions) inside the cavity 132 and with a tolerance of open spaces 816 on the sides of the DTC 130 so that a dielectric material can be disposed inside the open spaces 816 to insulate the DTC 130 in the core substrate 112. The DTC 130 was fabricated as a separate component in a separate process in this example. As shown in the exemplary fabrication stage 800E an FIG. 8E, the DTC 130 is disposed in the cavity 132 formed in the insulating layer 802 to prepare for embedding the DTC 130 in the core substrate 112 (block 710 in FIG. 7B). The DTC 130 is suspended inside the cavity 132 in this example so that a dielectric material can then be disposed around the open spaces 816 around the DTC 130 to insulate the DTC 130. In this regard, as shown in the exemplary fabrication stage 800E in FIG. 8E, the DTC 130 and more specifically its DTC interconnects 134, are coupled to an adhesive tape 818 that is then disposed on the metal interconnects 116 in the metal layer 814(1). This suspends the DTC 130 in the cavity 132 in a face-up direction towards the metal layer 814(1), which will be the die-side metal layer in an IC package. The adhesive tape 818 is also coupled to the metal interconnects 116 so that the DTC 130 is supported suspended inside the cavity 132. The DTC interconnects 134 being coupled to the adhesive tape 818, and the adhesive tape 818 being disposed over the metal interconnects 116 causes the DTC interconnects 134 to be disposed in the same metal layer 814(1) as the metal interconnects 116 so as to be disposed in the die-side outer metallization layer 118 when later formed.

Then, as shown in the exemplary fabrication stage 800F in FIG. 8F, while the DTC 130 is suspended face-up in the core substrate 112, the coreless metallization layer 624(1) is formed on the bottom side 808 of the insulating layer 802 by laminating a dielectric material 836 around the metal interconnects 628(1) and inside the open spaces 816 of the cavity 132 adjacent to the DTC 130 (block 712 in FIG. 7B). This secures the DTC 130 embedded within the insulating layer 802 of the core substrate 112. Also, using this fabrication process 700, the dielectric material 836 that is used to form the coreless metallization layer 624(1) is also the same dielectric material 836 that bounds the cavity 132 and is disposed around the DTC 130 to insulate the DTC 130. Thus, using this fabrication process 700, the DTC 130 can be insulated in the cavity 132 using the same fabricating process that is used to form the coreless metallization layer 624(1) of the package substrate 610.

Then, as shown in exemplary fabrication stage 800G in FIG. 8G, since the DTC 130 is secured inside the cavity 132 by the dielectric material 836 of the coreless metallization layer 624(1), the adhesive tape 818 shown in exemplary fabrication stage 800F in FIG. 8F can be removed (block 714 in FIG. 7C). This is to prepare the metallization layer 618 to be formed over metal layer 814(1) that includes the metal interconnects 116 and the DTC interconnects 134 as shown in the exemplary fabrication stage 800G in FIG. 8G as part of the formed package substrate 610 (block 714 in FIG. 7C). The metallization layer 618 is formed by laminating a dielectric material 820 on the metal layer 814(1) on the metal interconnects 116 and the DTC interconnects 134, and then forming an outer metal layer 838 on the metallization layer 618 (block 714 in FIG. 7C). The outer metallization layer 623 as a solder resist layer is also formed on the coreless metallization layer 624(3). A carrier 840 is then formed on the metal layer 838 so that the package substrate 610 can be handled to form the coreless metallization layers 624(2), 624(3) and the outer metallization layer 623 on the core substrate 112 as shown in the exemplary fabrication stage 800E in FIG. 8G (block 716 in FIG. 7C). Then, as shown in exemplary fabrication stage 800H in FIG. 8H, the carrier 840 and metal layer 838 are removed and dielectric material of the metallization layer 618 is processed to be thinned down to expose the metal interconnects 116 and DTC interconnects 134 so that connections can be established to the metal interconnects 116 and DTC interconnects 134 (block 716 in FIG. 7C).

Then, as shown in the exemplary fabrication stage 8001 in FIG. 8I, the solder resist layer 620 is disposed on the metallization layer 618 to prepare for a bumping process. Note that the outer metallization layer 623 could be formed at the same time as the solder resist layer 620 is formed. The humping process is performed to form the external metal interconnects 128 above the respective metal interconnects 116. DTC interconnects 134, and metal interconnects 622 in the openings 822, 824 of the respective outer die-side layer, solder resist layer 620 and solder resist layer 623 of the package substrate 610 above the respective metal interconnects 116, 622 (block 718 in FIG. 7D). The openings 1422, 1424 could be formed in the respective outer die-side layer, solder resist layer 620 and solder resist layer 623 at the same time. The bumping process forms the external metal interconnects 128 that are coupled to the respective metal interconnects 116 and DTC interconnects 134 in the outer metallization layer 620 as shown in exemplary fabrication stage 8001 in FIG. 8I (block 718 in FIG. 7D). The external metal interconnects 128 can be formed as solder balls, solder joints, metal posts, or other interconnects. As discussed above with reference to FIG. 6, the DTC interconnects 134 being disposed face-up towards the die-side outer metallization layer 620 and disposed in the metal layer 814(1) allows the DTC interconnects 134 to be directly coupled to the formed external metal interconnects 128 to provide a connection to die interconnects 126 of a die 108 that is disposed adjacent to the outer metallization layer 620 of the package substrate 610 when the IC package 602 in FIG. 6 is formed. This is to minimize the connection path length between the die 108 and the DTC 130.

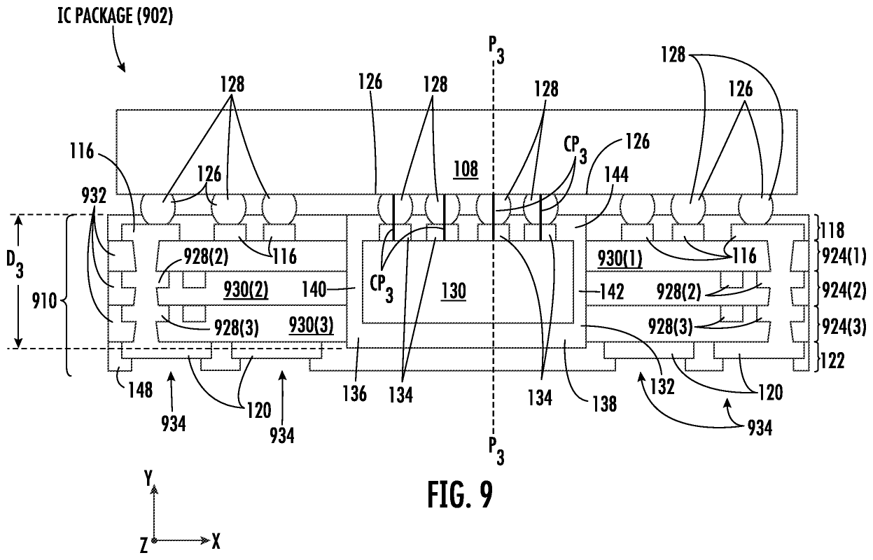

FIG. 9 illustrates a side view of another IC package 902 that includes a package substrate 910 that includes a DTC embedded face-up towards a die-side outer metallization layer of the package substrate, with DTC interconnects of the DTC connected to external, die-side interconnects disposed in a die-side outer metallization layer of the package substrate, to minimize the connection path length between the DTC and the die. The package substrate 910 is similar to the package substrate 110 in FIGS. 1A and 1B. However, as discussed in more detail below, the package substrate 910 in FIG. 9 is a coreless package substrate. The package substrate 910 in FIG. 9 does not include a core substrate like the package substrates 110 in FIGS. 1A and 1B and the package substrate 610 in FIG. 6, but includes coreless metallization layers 924(1)-924(3) with a DTC 130 embedded in the coreless metallization layers 924(1)-924(3). Common elements between the IC package 102 and package substrate 110 in FIGS. 1A and 1B and the IC package 902 and package substrate 910 in FIG. 9 are shown with common element numbers. The previous discussion of such common elements is applicable to the package substrate 910 in FIG. 9.

In this regard, as shown in FIG. 9, the coreless metallization layers 924(1)-924(3) are stacked on each other in a vertical direction (Z-axis direction). The coreless metallization layer 924(1) includes an insulating layer 930(1) made from a dielectric material 932 that is disposed adjacent to the die-side outer metallization layer 118. The coreless metallization layers 924(2), 924(3) are disposed adjacent to the coreless metallization layer 924(1) such that the coreless metallization layer 924(1) is disposed between the die-side outer metallization layer 118 and the coreless metallization layer 924(2) in a vertical direction (Z-axis direction). The coreless metallization layers 924(2), 924(3) include respective metal interconnects 928(2), 928(3) (e.g., metal traces, metal lines, metal posts) disposed in respective insulating layers 930(2), 930(2) that are also made from the dielectric material 938. The metal interconnects 928(2), 928(3) provide signal routing paths in the package substrate 910 to the metal interconnects 116 in the die-side outer metallization layer 118, which are coupled to the die 108. Again in this example, the die-side outer metallization layer 118 is a solder resist layer in this example. Metal interconnects 120 are disposed in a lower, outer metallization layer 122, which again is also referred to as a solder resist layer 122 for this example, since the outer metallization layer 122 is a solder resist layer in this example. The coreless metallization layers 924(1)-924(3) are disposed between the upper and lower solder resist layers 118, 122 in a vertical direction (Z-axis direction). The metal interconnects 928(3) in the coreless metallization layer 924(3) are coupled to metal interconnects 120 in the solder resist layer 122, which can then be coupled to external interconnects formed in openings 934 in the solder resist layer 122 to provide an external interface to the die 108.

With continuing reference to FIG. 9, and as discussed previously with regard to the package substrate 110 in FIGS. 1A and 1B, certain of the metal interconnects 116 of the outer metallization layer 118 of the package substrate 110 are disposed underneath the die 108 in a vertical direction (Z-axis direction) and electrically coupled to the die 108 to provide an electrical connection between the die 108 and the package substrate 110. In this regard, the die interconnects 126 of the die 108 are disposed above and coupled to respective external metal interconnects 128 in the die-side outer metallization layer 118 of the package substrate 110. The external metal interconnects 128 are formed in the solder resist layer as the die-side outer metallization layer 118 of the package substrate 110. The external metal interconnects 128 may be solder balls or ball grid array (BGA) interconnects as examples. The external metal interconnects 128 are coupled to respective metal interconnects 116 disposed the outer metallization layer 118 to couple the die 108 to the package substrate 110.

Also, as shown in FIG. 9, the arc 130 is provided in the package substrate 910 and coupled to the die 108 to provide a capacitor that is coupled to the die 108. To provide a design for package substrate 910 that minimizes the connection path length between the DTC 130 and the die 108 to reduce impedance and improve capacitor performance of the DTC 130, the DTC 130 is disposed face-up in a vertical direction (Z-axis direction) in the cavity 132 that is disposed in the package substrate 910. As discussed in more detail below, the cavity 132 is bounded by a dielectric material that insulates the DTC 130 from surrounding metal components in the package substrate 910. By face-up, it is meant that the DTC 130 is disposed in the package substrate 110 such that external metal interconnects 134 of the arc 130 (“DTC interconnects 134”) are oriented face-up towards the die-side outer metallization layer 118 and the die 108 of the IC package 102 in a vertical direction (Z-axis direction). By orienting the DTC interconnects 134 to be face-up towards to die-side outer metallization layer 118 and the die 108, the connection path length between the die 108 and the DTC 130 is reduced, because the connection paths do not have to be routed lower in a vertical direction (Z-axis direction) to reach the DTC interconnects 134 to establish a connection.

Also in this example, as shown in FIG. 9, to facilitate minimizing the connection path length between the embedded DTC 130 in the package substrate 910 and. the die 108, the arc 130 is embedded in the package substrate 910 such that the DTC 130 is disposed underneath the die 108 in a vertical direction (Z-axis direction). The DTC 130 and the die 108 share a common vertical plane P₃. The DTC 130 is also embedded in the coreless metallization layers 924(1)-924(3) such that the DTC interconnects 134 of the DTC 130 are disposed. In the die-side outer metallization layer 118 of the package substrate 110 directly below respective external metal interconnects 128 in the die-side outer metallization layer 118 in the vertical direction (Z-axis direction). In this manner, the DTC interconnects 134 can be directly connected to the external metal interconnects 128, which are connected to die interconnects 126 in this example, to provide an electrical connection between the DTC 130 and the die 108. By disposing the DTC 130 in the package substrate 110 such that the DTC interconnects 134 are disposed in the die-side outer metallization layer 118 in this example, the connection path length between the DTC 130 and the die 108, through the external metal interconnects 128 and the die interconnects 126, is minimized to minimize the inductance of the connection. Additional routing in the horizontal direction (X- and Y-axes directions) not required to connect the DTC 130 to the die 108 in this example.

Like the package substrate 110 in FIGS. 1A and 1B, the cavity 132 in the package substrate 910 in FIG. 9 is bounded by a dielectric material 136 on the bottom side 138, sides 140, 142, and the top side 144 to insulate the DTC 130 from the metal interconnects 116, 928(2), 928(3) in the die-side outer metallization layer 118 and the coreless metallization layers 924(1)-924(3) and other metal components in the package substrate 910. The DTC interconnects 134 are exposed from the first, upper face 146 of the DTC 130 such that the DTC interconnects 134 are disposed in the die-side outer metallization layer 118 of the package substrate 910. In this example, the portion of the die-side outer metallization layer 118 that is disposed above the upper face 146 of the DTC 130 forms the top side 144 of the cavity 132 that bounds the cavity 132. In this example, the dielectric material 136 that forms the bottom side 138, and sides 140, 142 is the same dielectric material 148 that the die-side outer metallization layer 118 and outer metallization layer 122 are made from, which are solder resist layers in this example. As will be discussed. In more detail below, when fabricating the package substrate 910, it may be efficient to dispose the dielectric material 136 in the package substrate 110 that forms the cavity 132 and as part of the same fabrication steps that are used to form the die-side outer metallization layer 118 and/or the outer metallization layer 122.

As shown in FIG. 9, the DTC 130 is embedded in the coreless metallization layers 924(1)-924(3) such that the DTC interconnects 134 of the DTC 130 are disposed in the die-side outer metallization layer 118 of the package substrate 910 directly below respective external metal interconnects 128 in the die-side outer metallization layer 118 in the vertical direction (Z-axis direction). In this manner, the DTC interconnects 134 can be directly connected to the external metal interconnects 128, which are connected to die interconnects 126 in this example, to provide an electrical connection between the DTC 130 and the die 108. This is shown by the connection paths CP₃ labeled in FIG. 9 between the die 108 and the DTC 130. By disposing the DTC 130 in the package substrate 910 such that the DTC interconnects 134 are disposed in the die-side outer metallization layer 118 in this example, the connection path length between the .DTC 130 and the die 108, through the external metal interconnects 128 and the die interconnects 126, is minimized to minimize the inductance of the connection. Additional routing in the horizontal direction (X- and Y-axes directions) is not required to provide the connection paths CP₃ between the DTC 130 to the die 108 in this example.

With continuing reference to FIG. 9, the cavity 132 in this example extends in a vertical direction (Z-axis direction) through the die-side outer metallization layer 118, the coreless metallization layers 924(1)-924(3), and the outer metallization layer 122. The cavity 132 should be formed in the package substrate 110 of a sufficient depth D₃ to support the volume needed to embed the DTC 130 of a desired size and capacity in the package substrate 910. As shown in FIG. 9, the metal interconnects 928(2), 928(3) can also be coupled to die 108 through metal interconnects 116 in the die-side outer metallization layer 118, connected to the external metal interconnects 128 in the die-side outer metallization layer 118 that connected to the die interconnects 126 of the die 108. These connections provide signal routing from the die 108 in the package substrate 910.

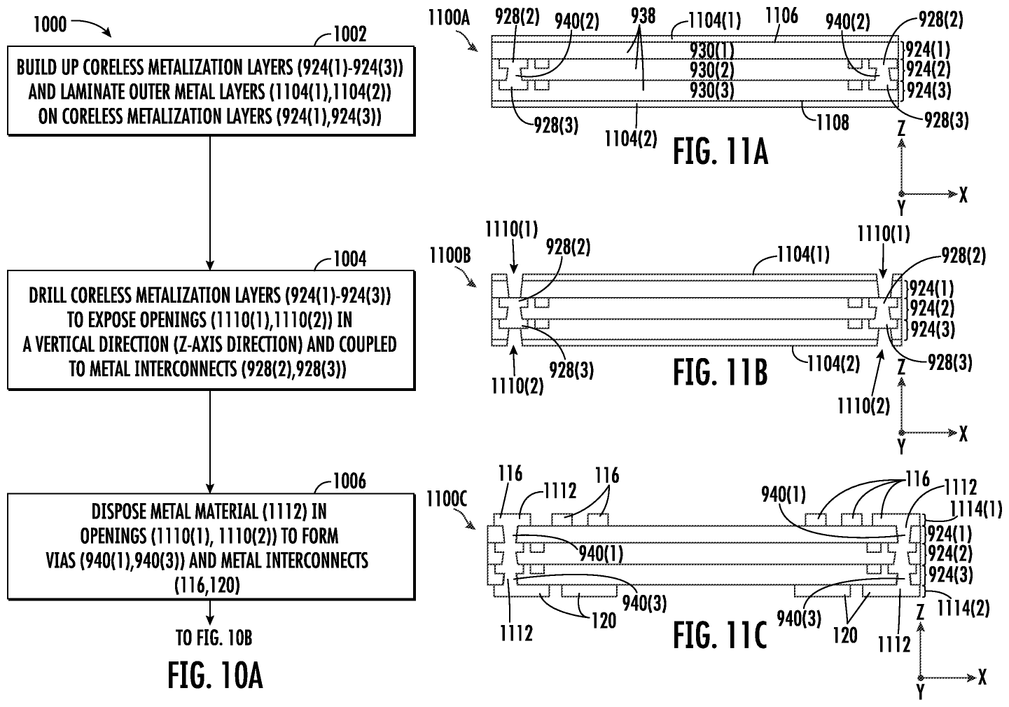

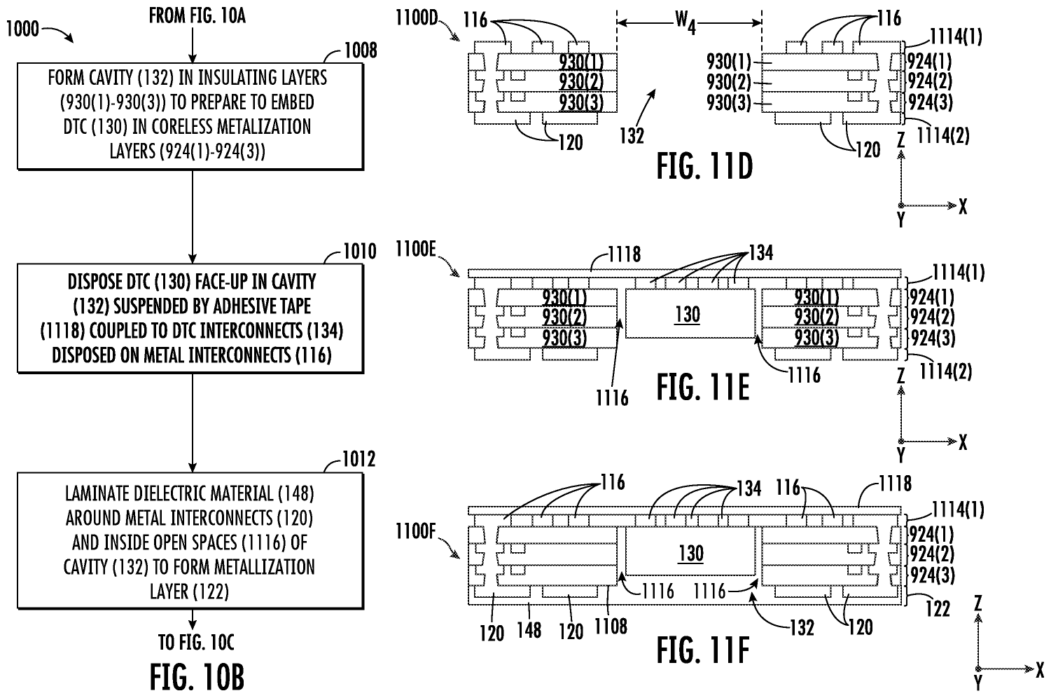

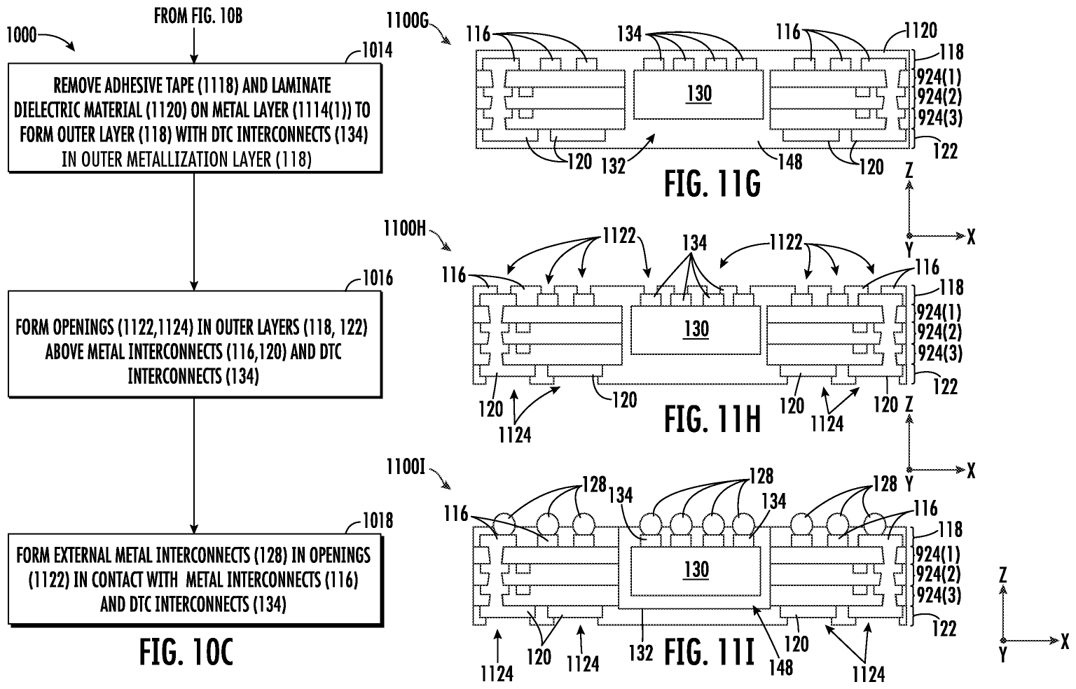

FIGS. 10A-10C is a flowchart illustrating another exemplary fabrication process 1000 of fabricating the package substrate 910 in FIG. 9. FIGS. 11A-11I are exemplary fabrication stages 1100A-11001 during fabrication of the package substrate 910 according to the fabrication process 1000 in FIGS. 10A-10C. The fabrication process 1000 in FIGS. 10A-10C, and as shown in the exemplary fabrication stages 1100A-1100I in FIGS. 11A-11I, will now be discussed in reference to the package substrate 910 in FIG. 9 as an example.

In this regard, as shown in the exemplary fabrication stage 1100A in FIG. 11A, the coreless metallization layers 924(1)-924(3) in the package substrate 910 in FIG. 9 are built up on top of each other (block 1002 in FIG. 10A). The coreless metallization layers 924(1)-924(3) are firmed from respective insulating layers 930(1)-930(3). For example, the dielectric material 938 of the insulating layers 930(1)-930(3) may be an organic resin material or inorganic filter material, Metal interconnects 928(2), 928(3) formed in the respective insulating layers 930(2), 930(3) are coupled together by vias 940(2) to form the respective coreless metallization layers 924(2), 924(3). Outer metal layers 1104(1), 1104(2) are disposed on the top side 1106 of the coreless metallization layer 924(1) and the, bottom side 1108 of coreless metallization layer 924(3) (block 1002 in FIG. 10A). Also as an example, the outer metal layers 1104(1), 1104(2) disposed on the top and bottom sides 1106, 1108 of the respective coreless metallization layers 924(1), 924(3) may be copper clad laminate (CCL) layers such that the core substrate is a CCL substrate. The top side 1106 of the coreless metallization layer 924(1) will eventually be on the die-side of an IC package when the package substrate is fully fabricated and used to fabricate an IC package.

Then, as shown in the exemplary fabrication stage 1100B in FIG. 11B, the coreless metallization layers 924(1), 924(3) are drilled, such as by laser drilling, to expose openings 1110(1), 1110(2) in a vertical direction (Z-axis direction) to prepare for respective vias 940(1), 940(3) to be formed in the respective coreless metallization layers 924(1), 924(3) and in electrical contact with the respective metal interconnects 928(2), 928(3) (block 1004 in FIG. 10A). The openings 1110(1), 1110(2) also prepare for the metal interconnects 116, 120 to be formed in the respective die-side outer metallization layer 118 and outer metallization layer 122 that will be formed (block 1004 in FIG. 10A). Then, as shown in the exemplary fabrication stage 11000 in FIG. 11C, a metal material 1112 is disposed in the openings 1110(1), 1110(2) to form the vias 940(1), 940(3) in the respective coreless metallization layers 924(1), 924(3) (block 1006 in FIG. 10A). The metal material 1112 is disposed over the surface of the outer metal layers 1104(1), 1104(2) acting as a seed layer, which is then patterned, such as through a lithography and etching process, to form respective metal interconnects 116, 120 in respective metal layers 1114(1), 1114(2). As discussed above with respect to FIG. 9, the metal interconnects 116 are coupled to external metal interconnects 128 that will be formed in a die-side outer metallization layer 118 formed on the metal layer 1114(1) to provide connection to a coupled die 108.

As shown in the exemplary fabrication stage 1100D in FIG. 11D, to prepare to embed the DTC 130 in the coreless metallization layers 924(1)-924(3), the cavity 132 is formed in the coreless metallization layers 924(1)-924(3) (block 1008 in FIG. 10B). The cavity 132 can be formed in the insulating layers 930(1)-930(3) of the coreless metallization layers 924(1)-924(3) by lithography patterning and etching or by drilling as examples. The width W4 of the cavity 132 should be formed so that the DTC 130 can be disposed width-wise in the horizontal direction (X- and Y-axes directions) inside the cavity 132 and with a tolerance of open spaces 1116 (as shown in exemplary fabrication stage 1100E in FIG. 11E) on the sides of the DTC 130 so that a dielectric material can be disposed inside the open spaces 1116 to insulate the DTC 130 in the coreless metallization layers 924(1)-924(3). The DTC 130 was fabricated as a separate component in a separate process in this example. As shown in the exemplary fabrication stage 1100E in FIG. 11E, the DTC 130 is disposed in the cavity 132 formed in the insulating layers 930(1)-930(3) to prepare for embedding the DTC 130 in the coreless metallization layers 924(1)-924(3) (block 1010 in FIG. 10B). The DTC 130 is suspended inside the cavity 132 in this example so that a dielectric material can then be disposed around the open spaces 1116 around the DTC 130 to insulate the DTC 130. In this regard, as shown in the exemplary fabrication stage 1100E in FIG. 11E, the DTC 130 and more specifically its DTC interconnects 134, are coupled to an adhesive tape 1118 that is then disposed on the metal interconnects 116 in the metal layer 1114(1) (block 1010 in FIG. 10B). This suspends the DTC 130 in the cavity 132 in a face-up direction towards the metal layer 1114(1), which will be the die-side metal layer in an IC package. The adhesive tape 1118 is also coupled to the metal interconnects 116 so that the DTC 130 is supported suspended inside the cavity 132. The DTC interconnects 134 being coupled to the adhesive tape 1118, and the adhesive tape 1118 being disposed over the metal interconnects 116 causes the DTC interconnects 134 to be disposed in the same metal layer 1114(1) as the metal interconnects 116 so as to be disposed in the die-side outer metallization layer 118 when later formed.

Then, as shown in the exemplary fabrication stage 1100F in FIG. 11F, while the DTC 130 is suspended face-up in the coreless metallization layers 924(1)-924(3), the outer metallization layer 122 as a solder resist layer is formed on the bottom side 1108 of the coreless metallization layer 924(3) by laminating a dielectric material 148 around the metal interconnects 120 and inside the open spaces 1116 of the cavity 132 adjacent to the DTC 130 (block 1012 in FIG. 10B). This secures the DTC 130 embedded within the insulating layers 930(1)-930(3) of the core substrate 912. Also, using this fabrication. process 1000, the dielectric material 148 that is used to form the outer metallization layer 122 is also the same dielectric material 148 that bounds the cavity 132 and is disposed around the DTC 130 to insulate the DTC 130. Thus, using this fabrication process 1000, the DTC 130 can be insulated in the cavity 132 using the same fabricating process that is used to form the outer metallization layer 122 of the package substrate 910. Then, as shown in the exemplary fabrication stage 1100G in FIG. 11G, since the DTC 130 is secured inside the cavity 132 by the dielectric material 148 of the outer metallization layer 122, the adhesive tape 1118 shown in exemplary fabrication stage 1100F in FIG. 11F can be removed (block 1014 in FIG. 10C). This is to prepare the die-side outer metallization layer 118 to be formed over metal layer 1114(1) that includes the metal interconnects 116 and the DTC interconnects 134 as shown in the exemplary fabrication stage 1100G in FIG. 11G as part of the formed package substrate 910 (block 1014 in FIG. 10C). The die-side outer metallization layer 118 is formed by laminating a dielectric material 1120 on the metal layer 1114(1) on the metal interconnects 116 and the DTC interconnects 134.

Then as shown in the exemplary fabrication stage 1100H in FIG. 11H, openings 1122, 1124 are formed in the respective outer metallization layers 118, 122 above the metal interconnects 116, 120, and DTC interconnects 134 of the package substrate 910 to expose the metal interconnects 116, 120, and DTC interconnects 134 from the outer metallization layers 118, 122 to be coupled as part of forming an package (block 1016 in FIG. 10C). Then, as shown in the exemplary fabrication stage 1100I in FIG. 11I, a bumping process is performed to form the external metal interconnects 128in the openings 1122, 1124 of the respective outer metallization layers 118, 122 of the package substrate 910 (block 1018 in FIG. 10C). The bumping process forms the external metal interconnects 128 that are coupled to the respective metal interconnects 116 and. DTC interconnects 134 in the outer metallization layer 118 as shown in exemplary fabrication stage 11001 in FIG. 11I (block 1018 in FIG. 10C). The external metal interconnects 128 can be formed as solder balls, solder joints, metal posts, or other interconnects. .As discussed above with reference to FIG. 9, the DTC interconnects 134 being disposed face-up towards the die-side outer metallization layer 118 and disposed in the metal layer 1114(1) allows the DTC interconnects 134 to be directly coupled to the formed external metal interconnects 128 to provide a connection to die interconnects 126 of a die 108 that is disposed adjacent to the outer metallization layer 118 of the package substrate 910 when the IC package 902 in. FIG. 9 is formed. This minimizes the connection path length between the die 108 and the DTC 130 in the package substrate 910.

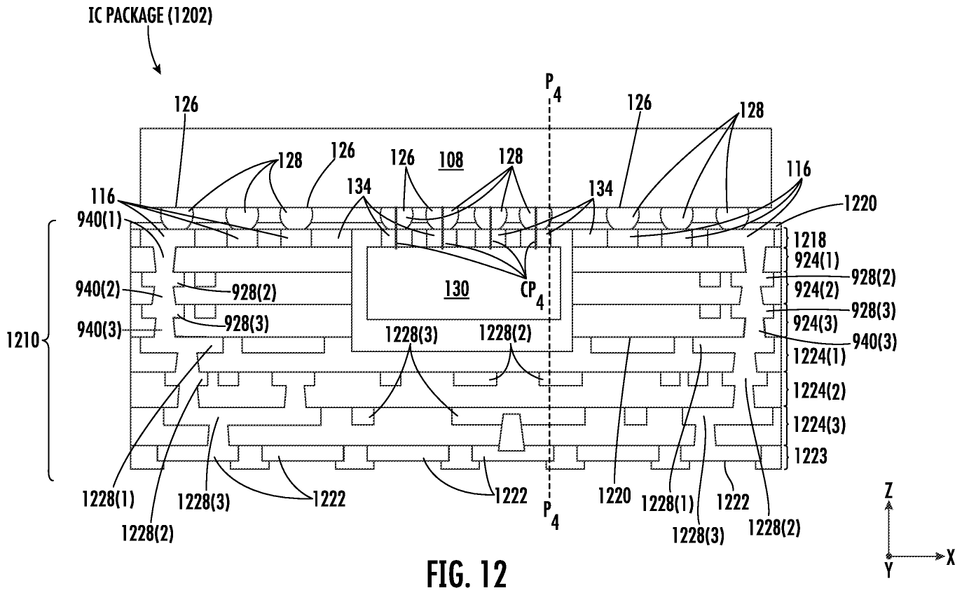

FIG. 12 is a side view of another exemplary IC package 1202 that includes a package substrate 1210 that is similar to the package substrate 910 in FIG. 9.

However, as discussed in more detail below, the package substrate 1210 in FIG. 12 has additional coreless metallization layers 1224(1)-1224(3) that are additionally built up on the coreless metallization layers 924(1)-924(3), below the coreless metallization layer 924(3) to form an asymmetric package substrate 1210. Common elements between the IC package 902 and package substrate 910 in FIG. 9 and the IC package 1202 and package substrate 1210 in FIG. 12 are shown with common element numbers. The previous discussion of such common elements is applicable to the package substrate 1210 in FIG. 12.

In this regard, with reference to FIG. 12, the metal interconnects 116 and the DTC interconnects 134 of the DTC 130 are disposed in a metallization layer 1218 that is die-side outer metallization layer of the package substrate 1210. The metallization layer 1218 is formed on the coreless metallization layer 924(1) and is similar to the outer metallization layer 118 of the package substrate 910 in FIG. 9. However, the metallization layer 1218 is not a solder resist layer in this example. A separate solder resist layer 1220 is disposed on the metallization layer 1218 as a die-side outer metallization layer 1220. The external metal interconnects 128 are disposed through the solder resist layer 1220 adjacent to the metallization layer 1218 and in contact with the metal interconnects 116 and DTC interconnects 134 in the metallization layer 1218 to couple the die 108 to the package substrate 1210 and to the DTC 130. The DTC 130 and the die 108 share a common vertical plane P₄ in a vertical direction (X- and Z-axes directions). The DTC 130 is embedded in the coreless metallization layers 924(1)-924(3) such that the DTC interconnects 134 of the DTC 130 are disposed in the metallization layer 1218 of the package substrate 1210 directly below respective external metal interconnects 128 in the die-side outer metallization layer 1220 in the vertical direction (Z-axis direction). In this manner, the DTC interconnects 134 can be directly connected to the external metal interconnects 128, which are connected to die interconnects 126, to provide an electrical connection between the DTC 130 and the die 108. This is shown by the connection paths CP₄ labeled in FIG. 12 between the die 108 and the DTC 130. By disposing the DTC 130 in the package substrate 1210 such that the DTC interconnects 134 are disposed in the metallization layer 1218 in this example, the connection path length between the DTC 130 and the die 108, through the external metal interconnects 128 and the die interconnects 126, is minimized to minimize the inductance of the connection. Additional routing in the horizontal direction (X- and Y-axes directions) is not required to provide the connection paths CP₄ between the DTC 130 to the die 108 in this example.

Also, as shown in FIG. 12, the package substrate 1210 includes the additional, second coreless metallization layers 1224(1)-1224(3) that are build-up on the bottom surface 1226 of the coreless metallization layer 924(3). The coreless metallization layers 924(1)-924(3) are disposed between the metallization layer 1218 and the second coreless metallization layers 1224(1)-1224(3). Each of the coreless metallization layers 1224(1)4224(3) includes respective metal interconnects 1228(1)4228(3) (e.g., metal traces, metal lines, metal posts) that can be connected to adjacent metal interconnects 1228(1)4228(3) in adjacent coreless metallization layers 1224(1)-1224(3) to provide signal routing paths in the package substrate 1210. Certain metal interconnects 1228(1) in the coreless metallization layer 1224(1) are connected to the metal interconnects 928(3) in the coreless metallization layer 924(3) to provide a signal routing path through the coreless metallization layers 924(1)-924(3) to the die 108. Certain metal interconnects 1228(3) in the coreless metallization layer 1224(3) are connected to the metal interconnects 1222 in a bottom, outer solder resist layer 1223 to provide a connection between the package substrate 910 and external metal interconnects (e.g., solder balls) formed in contact with the metal interconnects 1222.

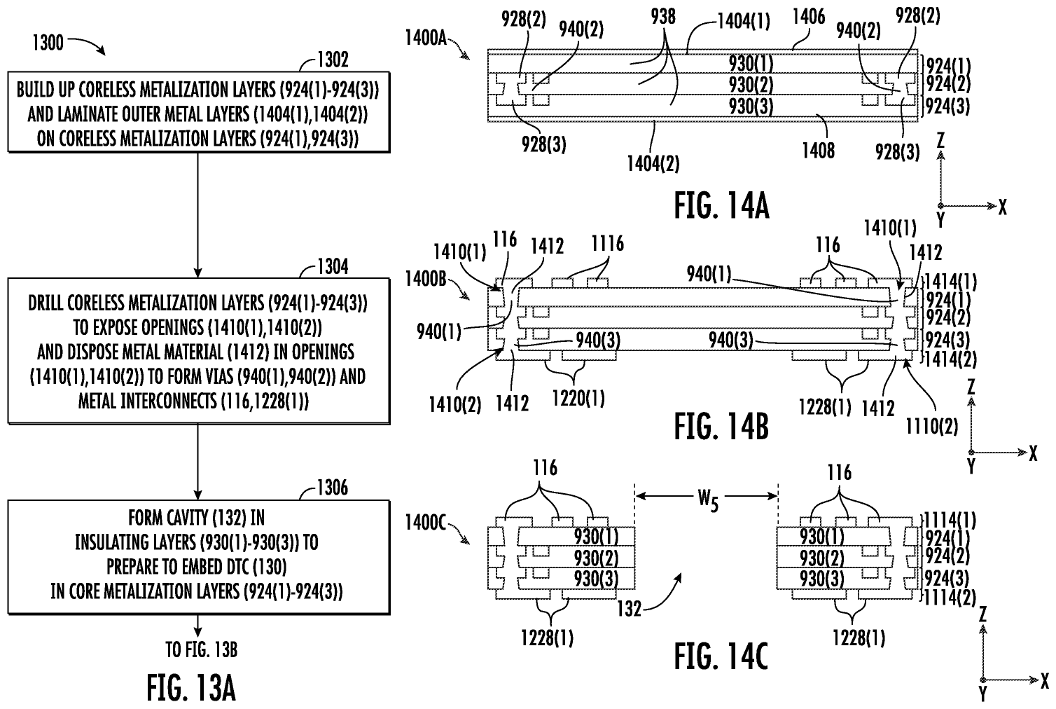

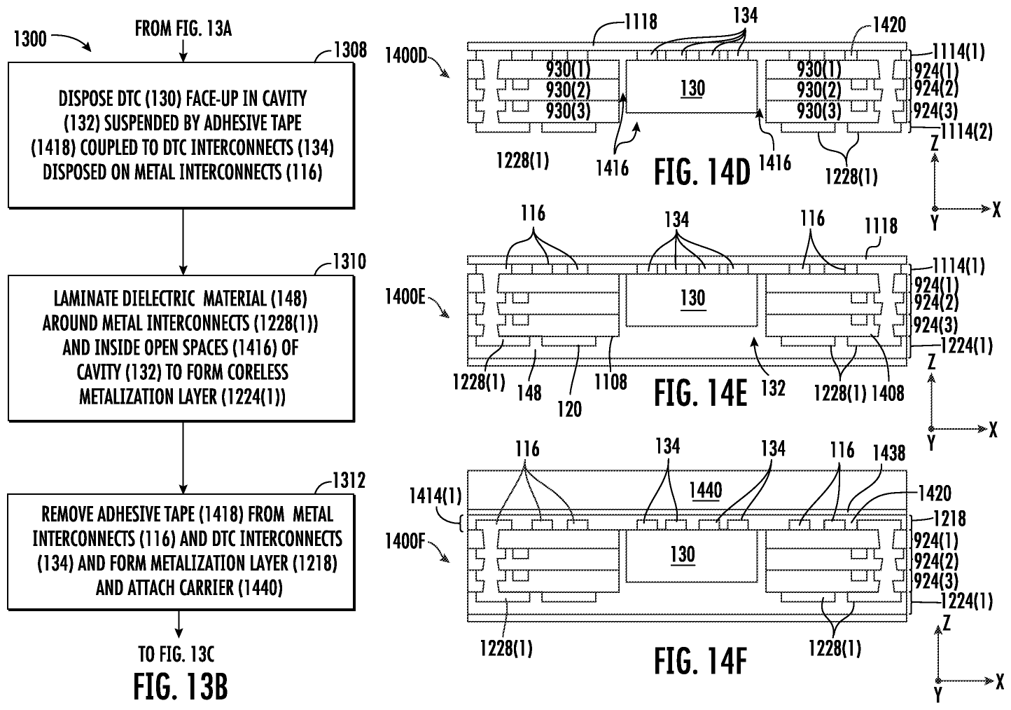

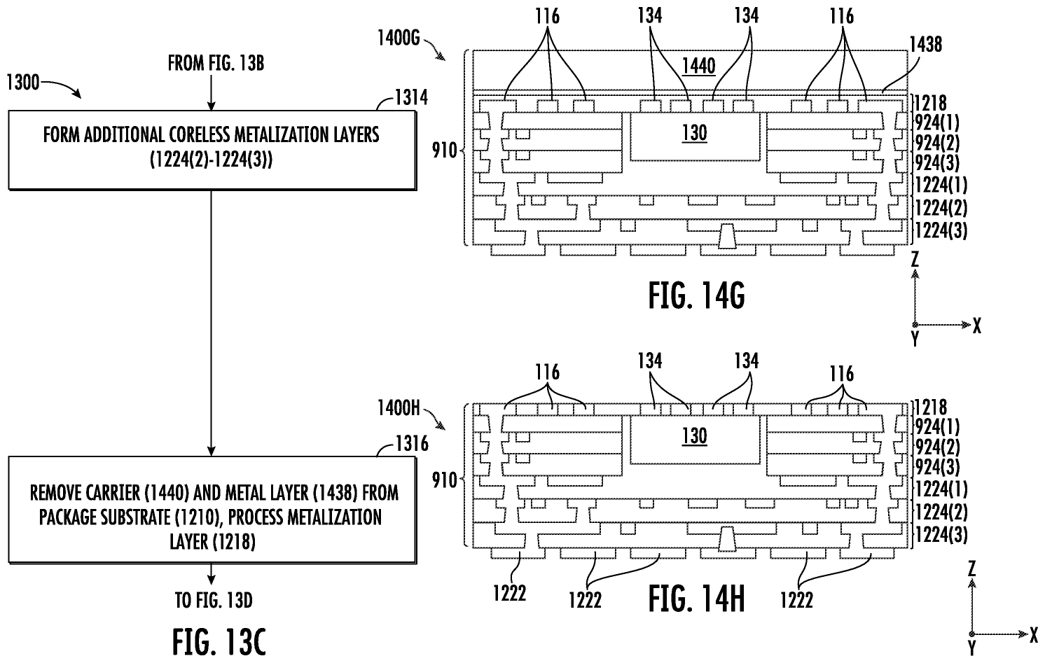

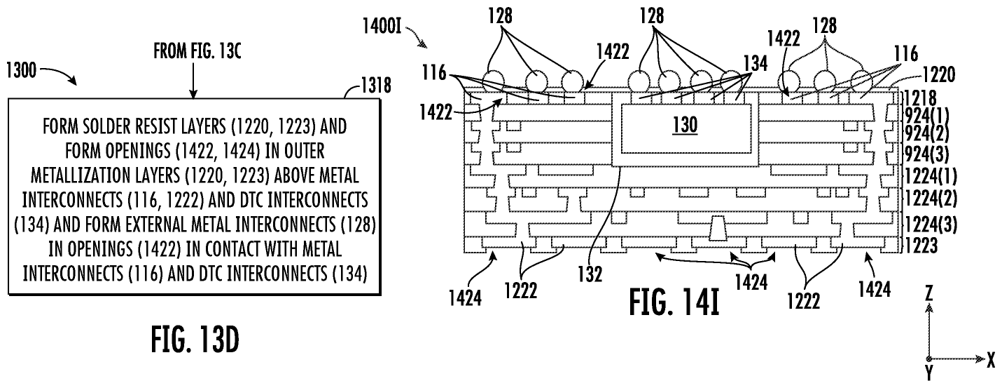

FIGS. 13A-13D is a flowchart illustrating another exemplary fabrication process 1300 of fabricating the package substrate 1210 in FIG. 12. FIGS. 14A-14I are exemplary fabrication stages 1400A-1400I during fabrication of the package substrate 1210 according to the fabrication process 1300 in FIGS. 13A-13D. The fabrication process 1300 in FIGS. 13A-13D, and as shown in the exemplary fabrication stages 1400A-1400I in FIGS. 14A-14I, will now be discussed in reference to the package substrate 1210 in FIG. 12 as an example.

In this regard, as shown in the exemplary fabrication stage 1400A in FIG. 14A, the coreless metallization layers 924(1)-924(3) in the package substrate 1210 in FIG. 12 are built up on top of each other (block 1302 in FIG. 13A). The coreless metallization layers 924(1)-924(3) are formed from respective insulating layers 930(1)-930(3). For example, the dielectric material 938 of the insulating layers 930(1)-930(3) may be an organic resin material or inorganic filter material, Metal interconnects 928(2), 928(3) formed in the respective insulating layers 930(2), 930(3) are coupled together by vias 940(2) to form the respective coreless metallization layers 924(2), 924(3). Outer metal layers 1104(1), 1104(2) are disposed on the top side 1406 of the coreless metallization layer 924(1) and the bottom side 1408 of coreless metallization layer 924(3) (block 1302 in FIG. 13A). Also as an example, the outer metal layers 1104(1), 1104(2) disposed on the top and bottom sides 1406, 1408 of the respective coreless metallization layers 924(1), 924(3) may be copper clad laminate (CCL) layers such that the core substrate is a CCL substrate. The top side 1406 of the coreless metallization layer 924(1) will eventually be on the die-side of an IC package when the package substrate is fully fabricated and used to fabricate an IC package.

Then, as shown in the exemplary fabrication stage 1400B in FIG. 14B, the coreless metallization layers 924(1), 924(3) are drilled, such as by laser drilling, to expose openings 1410(1), 1410(2) in a vertical direction (Z-axis direction) to prepare for respective vias 940(1), 940(3) to be formed in the respective coreless metallization layers 924(1), 924(3) and in electrical contact with the respective metal interconnects 928(2), 928(3) (block 1304 in FIG. 13A). The openings 1410(1), 1410(2) also prepare for the metal interconnect 116 and metal interconnect 1228(1) to be formed in the respective die-side outer metallization layer 118 and coreless metallization layer 1224(1) that will be formed (block 1304 in FIG. 13A). Then, as also shown in the exemplary fabrication stage 1400B in FIG. 14B, a metal material 1412 is disposed in the openings 1410(1), 1410(2) to form the vias 940(1), 940(3) in the respective coreless metallization layers 924(1), 924(3) (block 1304 in FIG. 13A). The metal material 1412 is disposed over the surface of the outer metal layers 1404(1), 1404(2) acting as a seed layer, which is then patterned, such as through a lithography and etching process, to form respective metal interconnects 116, 1228(1) in respective metal layers 1414(1), 1412(2). As discussed above with respect to FIG. 12, the metal interconnects 116 are coupled to external metal interconnects 128 that will be formed in a die-side outer metallization layer 118 formed on the metal layer 1414(1) to provide connection to a coupled die 108.

As shown in the exemplary fabrication stage 1400C in FIG. 14C, to prepare to embed the DTC 130 in the coreless metallization layers 924(1)-924(3), the cavity 132 is formed in the coreless metallization layers 924(1)-924(3) (block 1306 in FIG. 13A), The cavity 132 can be formed in the insulating layers 930(1)-930(3) of the coreless metallization layers 924(1)-924(3) by lithography patterning and etching or by drilling as examples. The width W₅ of the cavity 132 should be formed so that the DTC 130 can be disposed width-wise in the horizontal direction (X- and Y-axes directions) inside the cavity 132 and with a tolerance of open spaces 1416 (as shown in exemplary fabrication stage 1400D in FIG. 14D) on the sides of the DTC 130 so that a dielectric material can be disposed inside the open spaces 1416 to insulate the DTC 130 in the coreless metallization layers 924(1)-924(3). The DTC 130 was fabricated as a separate component in a separate process in this example. As shown in the exemplary fabrication stage 1400D in FIG. 14D, the DTC 130 is disposed in the cavity 132 formed in the insulating layers 930(1)-930(3) to prepare for embedding the DTC 130 in the coreless metallization layers 924(1)-924(3) (block 1308 in FIG. 13B). The DTC 130 is suspended inside the cavity 132 in this example so that a dielectric material can then be disposed around the open spaces 1116 around the DTC 130 to insulate the DTC 130,

In this regard, as shown in the exemplary fabrication stage 1400E in FIG. 14E, the DTC 130 and more specifically its DTC interconnects 134, are coupled to an adhesive tape 1418 that is then disposed on the metal interconnects 116 in the metal layer 1414(1) (block 1310 in FIG. 13B). This suspends the DTC 130 in the cavity 132 in a face-up direction towards the metal layer 1414(1), which will be the die-side metal layer in an IC package. The adhesive tape 1418 is also coupled to the metal interconnects 116 so that the DTC 130 is supported suspended inside the cavity 132. The DTC interconnects 134 being coupled to the adhesive tape 1418, and the adhesive tape 1418 being disposed over the metal interconnects 116, causes the DTC interconnects 134 to be disposed in the same metal layer 1414(1) as the metal interconnects 116 so as to be disposed in the metallization layers 1218 when later formed. Then, as shown in the exemplary fabrication stage 1400E in FIG. 14E, while the DTC 130 is suspended face-up in the coreless metallization layers 924(1)-924(3), the coreless metallization layer 1224(1) is formed on the bottom side 1408 of the coreless metallization layer 924(3) by laminating a dielectric material 148 around the metal interconnects 1228(1) and inside the open spaces 1416 of the cavity 132 adjacent to the DTC 130 (block 1310 in FIG. 13B). This secures the DTC 130 embedded within the insulating layers 930(1)-930(3) of the core substrate 912. Also, using this fabrication process 1300, the dielectric material 148 that is used to form the coreless metallization layer 1224(1) is also the same dielectric material 148 that bounds the cavity 132 and is disposed around the DTC 130 to insulate the DTC 130. Thus, using this fabrication process 1300, the DTC 130 can be insulated in the cavity 132 using the same fabricating process that is used to form the coreless metallization layer 1224(1) of the package substrate 1210.

Then, as shown in exemplary fabrication stage 1400F in FIG. 14F, since the DTC 130 is secured inside the cavity 132 by the dielectric material 148 of the coreless metallization layer 1224(1), the adhesive tape 1418 shown in exemplary fabrication stage 1400E in FIG. 14E can be removed (block 1312 in FIG. 13B). This is to prepare the metallization layer 1218 to be formed over metal layer 1414(1) that includes the metal interconnects 116 and the DTC interconnects 134 as shown in the exemplary fabrication stage 1400F in FIG. 14F as part of the formed package substrate 1210 (block 1312 in FIG. 13B). As shown in the exemplary fabrication stage 1400F in FIG. 14F, the metallization layer 1218 is formed by laminating a dielectric material 1420 on the metal layer 1414(1) on the metal interconnects 116 and the DTC interconnects 134, and then forming an outer metal layer 1438 on the metallization layer 1218 (block 1312 in FIG. 13B). The outer metallization layer 1223 as a solder resist layer is also formed on the coreless metallization layer 624(3). A carrier 1440 is then formed and attached on the metal layer 1438 so that the package substrate 1210 can be handled to form the outer coreless metallization layers 1224(3), 1224(3) and the outer metallization layer 1223 as shown in the exemplary fabrication stage 1400G in FIG. 14G (block 1314 in FIG. 13C). Then, as shown in exemplary fabrication stage 1400H1 in FIG. 14H, the carrier 1440 and metal layer 1438 are removed and dielectric material of the metallization layer 1218 is processed to be thinned down to form the final metallization layer 1218 (block 1316 in FIG. 13C).

Then, as shown in the exemplary fabrication stage 14001 in FIG. 14I, the lower solder resist layer 1223 is formed (e.g., laminated) on the bottom coreless metallization layer 1224(3) and patterned to form openings 1424 above the metal interconnects 1222 to expose the metal interconnects 1222 for connection (block 1318 in FIG. 13D). Also, the solder resist layer 1220 is formed (e.g., laminated) on the metallization layer 1218 and patterned to form openings 1422 above the metal interconnects 116 and DTC interconnects 134 to expose such to prepare for a bumping process (block 1318 in FIG. 13D). Note that the lower solder resist layer 1223 could be formed on the bottom coreless metallization layer 1224(3) at the same time as the solder resist layer 1220 is formed on the metallization layer 1218. The bumping process is performed to form the external metal interconnects in openings 1422, 1424 of the respective outer die-side layer, solder resist layer 1220 and solder resist layer 1223 of the package substrate 1210 above the respective metal interconnects 116. DTC interconnects 134, and metal interconnects 1222 (block 1318 in FIG. 13D). The openings 1422, 1424 could be formed in the respective outer die-side layer, solder resist layer 1220 and solder resist layer 1223 at the same time. The bumping process forms the external metal interconnects 128 that are coupled to the respective metal interconnects 116 and DTC interconnects 134 in the outer metallization layer 1220 as shown in the exemplary fabrication stage 14001 in FIG. 14I (block 1318 in FIG. 13D). The external metal interconnects 128 can be formed as solder balls, solder joints, metal posts, or other interconnects. As discussed above with reference to FIG. 12, the DTC interconnects 134 being disposed face-up towards the die-side outer metallization layer 1220 and disposed in the metallization layer 1218 allows the DTC interconnects 134 to be directly coupled to the formed external metal interconnects 128 to provide a connection to die interconnects 126 of a die 108 that is disposed adjacent to the outer metallization layer 1220 of the package substrate 1210 when the IC package 1202 in FIG. 12 is formed, This is to minimize the connection path length between the die 108 and the DTC 130.

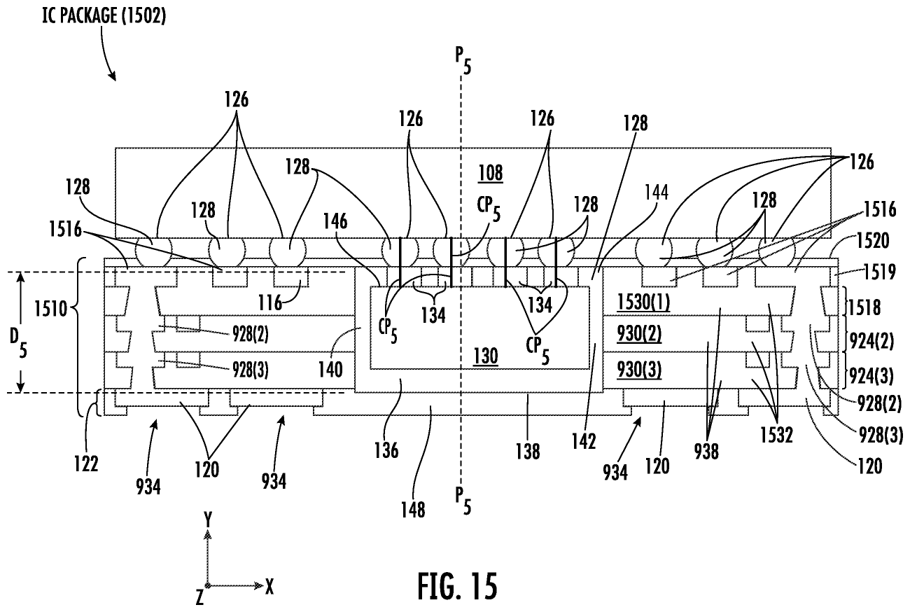

FIG. 15 illustrates a side view of another IC package 1502 that includes a package substrate 1510 that includes a DTC embedded face-up towards a die-side outer metallization layer of the package substrate, with DTC interconnects of the DTC connected to external, die-side interconnects disposed in a die-side outer metallization layer of the package substrate, to minimize the connection path length between the DTC and the die. The package substrate 1510 is similar to the package substrate 910 in FIG. 9. However, as discussed in more detail below, the package substrate 1510 in. FIG. 15 is an ETS package substrate. The package substrate 1510 includes an ETS metallization layer 1518 that has the metal traces 1516 (“embedded metal traces 1516”) embedded in an insulating layer 1519. The ETS metallization layer 1518 is disposed on additional coreless metallization layers 924(2)-924(3), like present in the package substrate 910 in FIG. 9, with a DTC 130 embedded in the ETS metallization layer 1518 and the coreless metallization layers 924(2)-924(3). Common elements between the IC package 902 and package substrate 910 in FIG. 9 and the IC package 1502 and package substrate 1510 in FIG. 15 are shown with common element numbers. The previous discussion of such common elements is also applicable to the package substrate 1510 in FIG. 15.

In this regard, as shown in FIG. 15, the coreless metallization layers 924(2), -924(3) are stacked on each other in a vertical direction (Z-axis direction). The coreless metallization layer 924(2) includes an insulating layer 930(2) made from a dielectric material 932 that is disposed adjacent to the ETS metallization layer 1518. The ETS metallization layer 1518 is an insulating layer 1530(1) with the embedded metal traces 1516. The coreless metallization layers 924(2), 924(3) are disposed adjacent to the ETS metallization layer 1518 such that the coreless metallization layer 924(2) is disposed between the ETS metallization layer 1518 and the coreless metallization layer 924(3) in a vertical direction (Z-axis direction). The coreless metallization layers 924(2), 924(3) include respective metal interconnects 928(2), 928(3) (e,g., metal traces, metal lines, metal posts) disposed respective insulating layers 930(2), 930(3) that are also made from the dielectric material 938. The metal interconnects 928(2), 928(3) provide signal routing paths in the package substrate 1510 to the embedded metal traces 1516 in the ETS metallization layer 1518, which are coupled to the die 108. The ETS metallization layer 1518 is disposed adjacent to a die-side outer metallization layer 1520, which is a solder resist layer in this example. The die-side outer metallization layer 1520 is named a “die-side” layer, because a die-side outer metallization layer 1520 is adjacent to the die 108. Metal interconnects 120 are disposed in a lower, outer metallization layer 122, which is also referred to as a solder resist layer 122 since the outer metallization layer 122 is a solder resist layer in this example, and thus also referred to as a “solder resist layer 122.” The ETS metallization layer 1518 and the coreless metallization layers 924(2)-924(3) are disposed between the die-side outer metallization layer 1520 and the outer metallization layer 122 in a vertical direction (Z-axis direction). The metal interconnects 928(3) in the coreless metallization layer 924(3) are coupled to metal interconnects 120 in the solder resist layer 122, which can then be coupled to external interconnects formed in openings 934 in the solder resist layer 122 to provide an external interface to the die 108.

With continuing reference to FIG. 15, and as discussed previously with. regard to the package substrate 910 in FIG. 9, certain of the embedded metal traces 1516 of the ETS metallization layer 1518 of the package substrate 1510 are disposed underneath the die 108 in a vertical direction (Z-axis direction) and electrically coupled to the die 108 to provide an electrical connection between the die 108 and the package substrate 1510. In this regard, the die interconnects 126 of the die 108 are disposed above and coupled to respective external metal interconnects 128 in the die-side outer metallization layer 1520 of the package substrate 1510. The external metal interconnects 128 are formed in the solder resist layer as the die-side outer metallization layer 1520 of the package substrate 1510. The external metal interconnects 128 may be solder balls or ball grid array (BGA) interconnects as examples. The external metal interconnects 128 are coupled to respective embedded metal traces 1516 disposed the outer metallization layer 118 to couple the die 108 to the package substrate 1510.

Also, as shown in FIG. 15, the DTC 130 is provided in the package substrate 1510 and coupled to the die 108 to provide a capacitor that is coupled to the die 108. To provide a design for package substrate 1510 that minimizes the connection path length between the DTC 130 and the die 108 to reduce impedance and improve capacitor performance of the DTC 130, the DTC 130 is disposed face-up in a vertical direction (Z-axis direction) in the cavity 132 that is disposed in the package substrate 1510. As discussed in more detail below, the cavity 132 is bounded by a dielectric material that insulates the DTC 130 from surrounding metal components in the package substrate 1510, By face-up, it is meant that the DTC 130 is disposed in the package substrate 1510 such that external metal interconnects 134 of the DTC 130 (“DTC interconnects 134”) are oriented face-up towards the die-side outer metallization layer 1520 and the die 108 of the IC package 102 in a vertical direction (Z-axis direction). By orienting the DTC interconnects 134 to be face-up towards to die-side outer metallization layer 1520 and the die 108, the connection path length between the die 108 and the DTC 130 is reduced, because the connection paths do not have to be routed lower in a vertical direction (Z-axis direction) to reach the DTC interconnects 134 to establish a connection.

Also in this example, as shown in FIG. 15, to facilitate minimizing the connection path length between the embedded arc 130 in the package substrate 1510 and the die 108, the DTC 130 is embedded in the package substrate 1510 such that the DTC 130 is disposed underneath the die 108 in a vertical direction (Z-axis direction). The DTC 130 and the die 108 share a common vertical plane P₅. The DTC 130 is also embedded in the ETS metallization layer 1518 and the coreless metallization layers 924(2)-924(3) such that the DTC interconnects 134 of the DTC 130 are disposed in the ETS metallization layer 1518 of the package substrate 1510 directly below respective external metal interconnects 128 in the die-side outer metallization layer 1520 in the vertical direction (Z-axis direction). In this manner, the DTC interconnects 134 can be directly connected to the external metal interconnects 128, which are connected to die interconnects 126 in this example, to provide an electrical connection between the DTC 130 and the die 108. By disposing the .DTC 130 in the package substrate 110 such that the DTC interconnects 134 are disposed in the ETS metallization layer 1518 in this example, the connection path length between the DTC 130 and the die 108, through the external metal interconnects 128 and the die interconnects 126, is minimized to minimize the inductance of the connection. Additional routing in the horizontal direction (X- and Y-axes directions is not required to connect the arc 130 to the die 108 in this example.

Like the package substrate 910 in FIG. 9, the cavity 132 in the package substrate 1510 in FIG. 15 is bounded by a dielectric material 136 on the bottom side 138, sides 140, 142, and the top side 144 to insulate the DTC 130 from the embedded metal traces 1516 in the ETS metallization layer 1518 and the metal interconnects 928(2), 928(3) of the coreless metallization layers 924(2)-924(3) and other metal components in the package substrate 1510. The DTC interconnects 134 are exposed from the first, upper face 146 of the DTC 130 such that the arc interconnects 134 are disposed in the ETS metallization layer 1518 of the package substrate 1510. In this example, the portion of the ETS metallization layer 1518 that is disposed above the upper face 146 of the DTC 130 forms the top side 144 of the cavity 132 that bounds the cavity 132. In this example, the dielectric material 136 that forms the bottom side 138, and sides 140, 142 is the same dielectric material 148 that the outer metallization layer 122 is made from, which is a solder resist layer in this example. As will be discussed in more detail below, when. fabricating the package substrate 1510, it may be efficient to dispose the dielectric material 136 in the package substrate 1510 that forms the cavity 132 and as part of the same fabrication steps that are used to form the outer metallization layer 122.

As shown in FIG. 15, the DTC 130 is embedded in the ETS metallization layer 1518 and the coreless metallization layers 924(2)-924(3) such that the DTC interconnects 134 of the DTC 130 are disposed in the ETS metallization layer 1518 of the package substrate 1510 directly below respective external metal interconnects 128 in the die-side outer metallization layer 1520 in the vertical direction (Z-axis direction). In this manner, the DTC interconnects 134 can be directly connected to the external metal interconnects 128, which are connected to die interconnects 126 in this example, to provide an electrical connection between the DTC 130 and the die 108. This is shown by the connection paths CP₅ labeled in FIG. 15 between the die 108 and the DTC 130. By disposing the DTC 130 in the package substrate 1510 such that the DTC interconnects 134 are disposed in the ETS metallization layer 1518 in this example, the connection path length between the DTC 130 and the die 108, through the external metal interconnects 128 and the die interconnects 126, is minimized to minimize the inductance of the connection. Additional routing in the horizontal direction (X- and Y-axes directions) is not required to provide the connection paths CP₅ between the DTC 130 to the die 108 in this example.

With continuing reference to FIG. 15, the cavity 132 in this example extends in a vertical direction (Z-axis direction) through the ETS metallization layer 1518, the coreless metallization layers 924(2)-924(3), and the outer metallization layer 122. The cavity 132 should be formed in the package substrate 1510 of a sufficient depth D₅ to support the volume needed to embed the DTC 130 of a desired size and capacity in the package substrate 1510. As shown in FIG. 15, the metal interconnects 928(2), 928(3) can also be coupled to die 108 through embedded metal traces 1516 in the ETS metallization layer 1518, connected to the external metal interconnects 128 in the die-side outer metallization layer 1520 that connected to the die interconnects 126 of the die 108. These connections provide signal routing from the die 108 in the package substrate 1510,

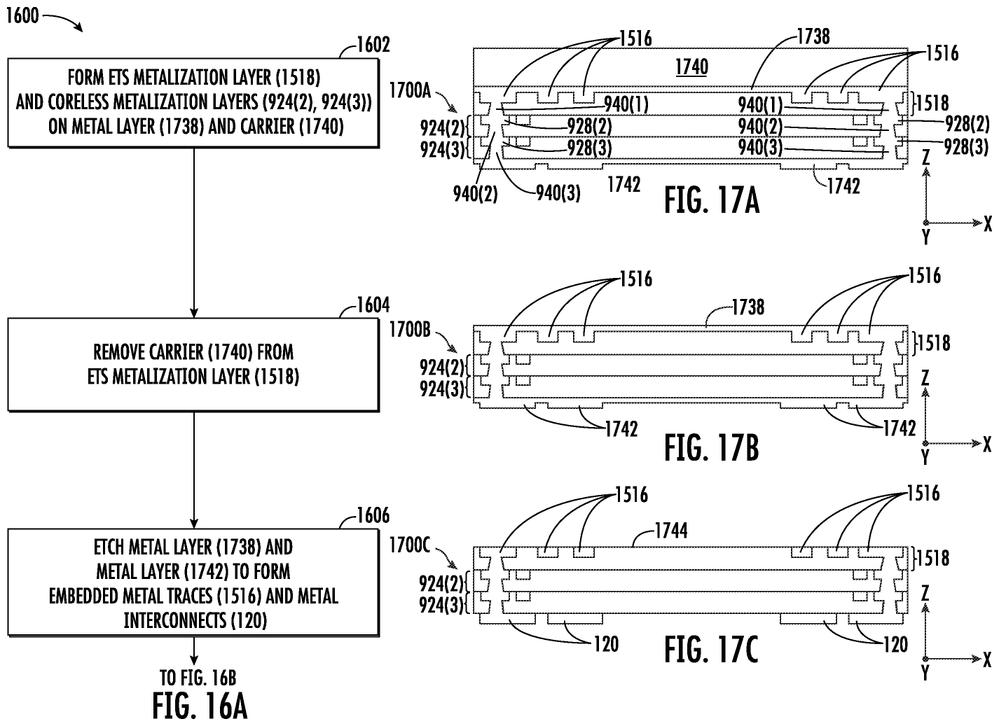

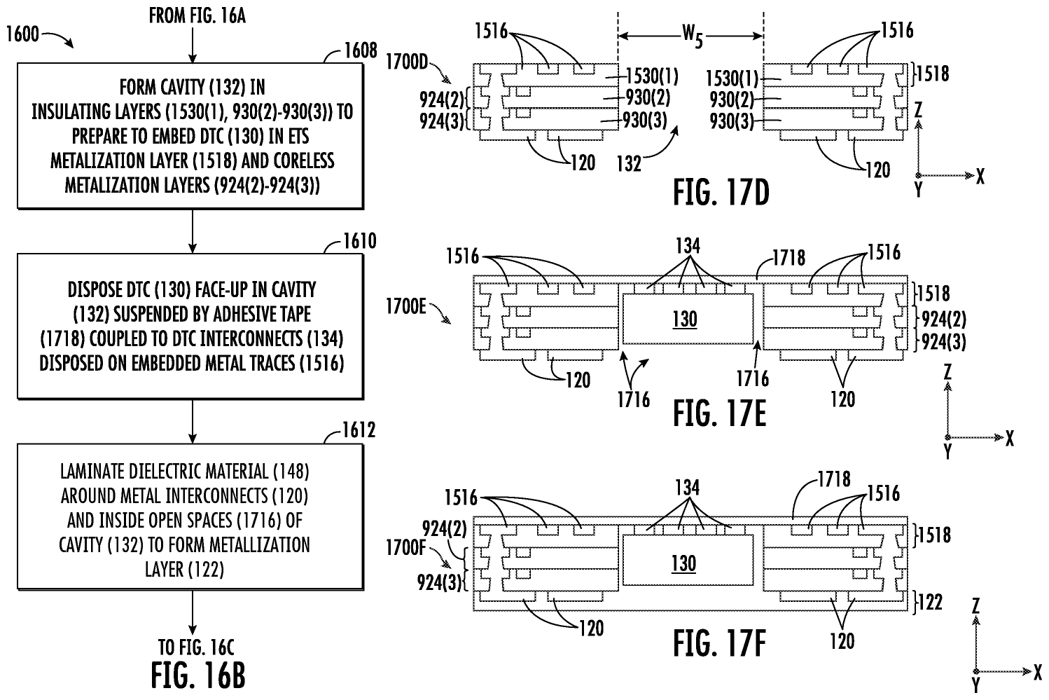

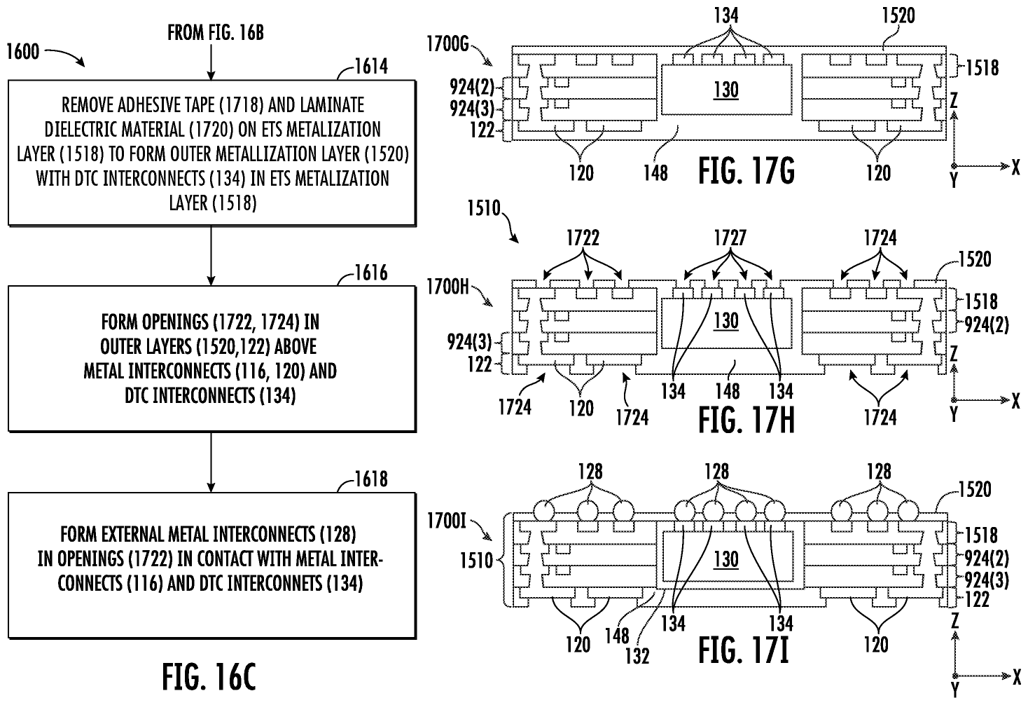

FIGS. 16A-16C is a flowchart illustrating another exemplary fabrication process 1600 of fabricating the package substrate 1510 in. FIG. 15. FIGS. 17A-17I are exemplary fabrication stages 1700A-1700I during fabrication of the package substrate 1510 according to the fabrication process 1600 in FIGS. 16A-16C. The fabrication. process 1600 in FIGS. 16A-16C, and as shown in the exemplary fabrication stages 1700A-17001 in FIGS. 17A-17I, will now be discussed in reference to the package substrate 1510 in FIG. 15 as an example.

In this regard, as shown in the exemplary fabrication stage 1700A in FIG. 17A, the ETS metallization layer 1518 and the coreless metallization layers 924(2), 924(3) are formed on a metal layer 1738 that is attached to a carrier 1740 and stacked on top of each other in the vertical direction (Z-axis direction) (block 1602 in FIG. 16A). The ETS metallization layer 1518 and the coreless metallization layers 924(2), 924(3) can be formed using lamination processes. The carrier 1740 allows the ETS metallization layer 1518 and the coreless metallization layers 924(2), 924(3) to be processed to form the embedded metal traces 1516 and metal interconnects 928(2), 928(3) interconnected by respective vias 940(1)-940(3). For example, the ETS metallization layer 1518 and the coreless metallization layers 924(2), 924(3) may be drilled with a metal material disposed in the drilled openings to form the vias 940(1)-940(3) and which provides a residual metal layer 1742 on the coreless metallization layer 924(3). Next, as shown in the exemplary fabrication stage 170013 in FIG. 17B, the carrier 1740 is detached to prepare the ETS metallization layer 1518 and the coreless metallization layers 924(2), 924(3) to be processed and etched to planarize the embedded metal traces 1516 with a top surface 1744 of the ETS metallization layer 1518 (block 1604 in FIG. 16A). As shown in the exemplary fabrication stage 17000 in FIG. 17C, the ETS metallization layer 1518 and the metal layer 1742 are etched to planarize and expose the embedded metal traces 1516 with the top surface 1744 of the ETS metallization layer 1518 and to planarize and expose the metal interconnects 120 (block 1606 in FIG. 16A).

As shown in the exemplary fabrication stage 1700D in FIG. 17D, to prepare to embed the DTC 130 in the FITS metallization layer 1518 and the coreless metallization layers 924(2)-924(3), the cavity 132 is formed in the ETS metallization layer 1518 and the coreless metallization layers 924(2)-924(3) (block 1608 in FIG. 16B). The cavity 132 can be formed in the insulating layer 1530(1) of the ETS metallization layer 1518 and the insulating layers 930(2)-930(3) of the coreless metallization layers 924(2)-924(3) by lithography patterning and etching or by drilling as examples. The width W₅ of the cavity 132 should be formed so that the DTC 130 can be disposed width-wise in the horizontal direction (X- and Y-axes directions) inside the cavity 132 and with a tolerance of open spaces 1716 (as shown in exemplary fabrication stage 1700E in FIG. 17E) on the sides of the DTC 130 so that a dielectric material can be disposed inside the open spaces 1716 to insulate the DTC 130 in the ETS metallization layer 1518 and the coreless metallization layers 924(2)-924(3). The DTC 130 was fabricated as a separate component in a separate process in this example.

As shown in the exemplary fabrication stage 1700E in FIG. 17E, the DTC 130 is disposed in the cavity 132 formed in the insulating layer 1530(1) of the ETS metallization layer 1518 and the insulating layers 930(2)-930(3) of the coreless metallization layers 924(2)-924(3) to prepare for embedding the DTC 130 in the ETS metallization layer 1518 and the coreless metallization layers 924(2)-924(3) (block 1610 in FIG. 16B). The DTC 130 is suspended inside the cavity 132 in this example so that a dielectric material can then be disposed around the open spaces 1716 around the DTC 130 to insulate the DTC 130. In this regard, as shown in the exemplary fabrication stage 1700E in FIG. 17E, the DTC 130 and more specifically its DTC interconnects 134, are coupled to an adhesive tape 1718 that is then disposed on the embedded metal traces 1516 in the ETS metallization layer 1516 (block 1610 in FIG. 16B). This suspends the DTC 130 in the cavity 132 in a face-up direction towards the ETS metallization layer 1518. The adhesive tape 1718 is also coupled to the embedded metal traces 1516 of the ETS metallization layer 1518 so that the DTC 130 is supported suspended inside the cavity 132. The DTC interconnects 134 being coupled to the adhesive tape 1718, and the adhesive tape 1718 being disposed over the embedded metal traces 1516 causes the DTC interconnects 134 to be disposed in the same metal layer as the embedded metal traces 1516 in the ETS metallization layer 1518 when later formed.

Then, as shown in the exemplary fabrication stage 1700F in FIG. 17F, while the DTC 130 is suspended face-up in the ETS metallization layer 1518 and the coreless metallization layers 924(2)-924(3), the outer metallization layer 122 as a solder resist layer is formed on the bottom side 1708 of the coreless metallization layer 924(3) by laminating a dielectric material 148 around the metal interconnects 120 and inside the open spaces 1716 of the cavity 132 adjacent to the DTC 130 (block 1612 in FIG. 16B). This secures the DTC 130 embedded within the ETS metallization layer 1518 and the coreless metallization layers 924(2)-924(3). Also, using this fabrication process 1600, the dielectric material 148 that is used to form the outer metallization layer 122 is also the same dielectric material 148 that bounds the cavity 132 and is disposed around the arc 130 to insulate the DTC 130. Thus, using this fabrication process 1600, the DTC 130 can be insulated in the cavity 132 using the same fabricating process that is used to form the outer metallization layer 122 of the package substrate 1510. Then, as shown in the exemplary fabrication stage 1700G in FIG. 17G, since the DTC 130 is secured inside the cavity 132 by the dielectric material 148 of the outer metallization layer 122, the adhesive tape 1718 shown in exemplary fabrication stage 1700F in FIG. 17F can be removed (block 1614 in FIG. 16C). This is to prepare the die-side outer metallization layer 1520 to be formed over ETS metallization layer 1518 that includes the embedded metal traces 1516 and the DTC interconnects 134 as shown in the exemplary fabrication stage 1700G in FIG. 17G as part of the formed package substrate 1512 (block 1614 in FIG. 16C). The die-side outer metallization layer 1520 is formed by laminating a dielectric material 1720 on the ETS metallization layer 1518 on the embedded metal traces 1516 and the DTC interconnects 134.

Then, as shown in the exemplary fabrication stage 1700H in FIG. 17H, openings 1722, 1724 are formed in the outer metallization layers 1520, 122 above the respective embedded metal traces 1516 and DTC interconnects 134, and metal interconnects 120 of the package substrate 1510 to expose the embedded metal traces 1516 and DTC interconnects 134, and metal interconnects 120 from the respective outer metallization layers 1520, 122 to be coupled as part of forming an IC package (block 1616 in FIG. 16C). Then, as shown in the exemplary fabrication stage 1700I in FIG. 17I, a bumping process is performed to form the external metal interconnects 128 in the openings 1722, 1724 of the respective outer metallization layers 1520, 122 of the package substrate 1510 (block 1618 in FIG. 16C). The bumping process forms the external metal interconnects 128 that are coupled to the respective embedded metal traces 1516 and DTC interconnects 134 in the outer metallization layer 1520 as shown in the exemplary fabrication stage 17001 in FIG. 17I (block 1618 in FIG. 16C). The external metal interconnects 128 can be formed as solder balls, solder joints, metal posts, or other interconnects. As discussed above with reference to FIG. 15, the DTC interconnects 134 being disposed face-up towards the die-side outer metallization layer 1520 and disposed in the ETS metallization layer 1518 allows the DTC interconnects 134 to be directly coupled to the formed external metal interconnects 128 to provide a connection to die interconnects 126 of a die 108 that is disposed adjacent to the outer metallization layer 122 of the package substrate 1510 when the IC package 1502 in FIG. 15 is formed This minimizes the connection path length between the die 108 and the DTC 130 in the package substrate 1510.

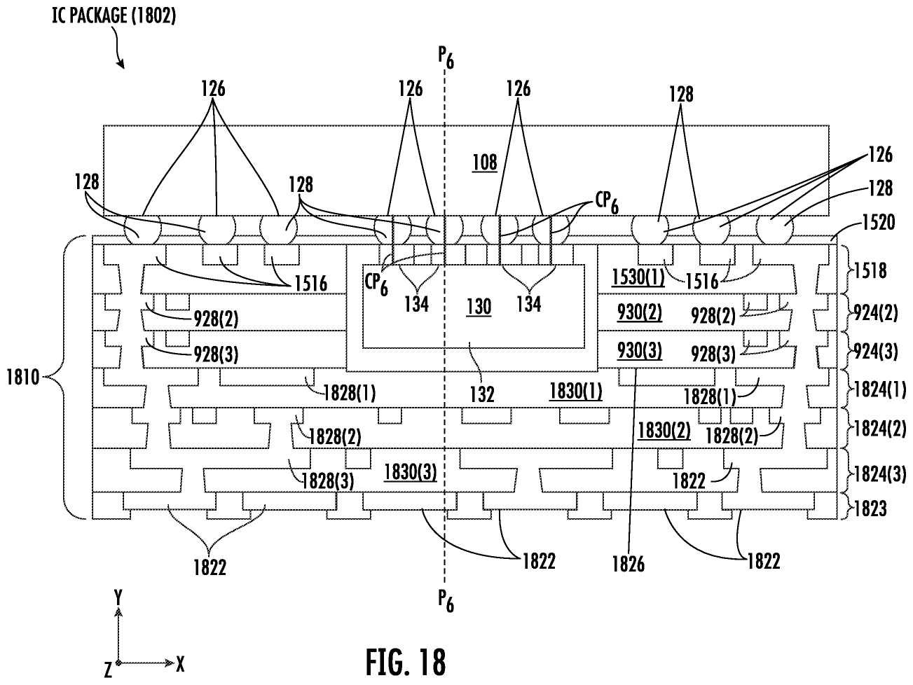

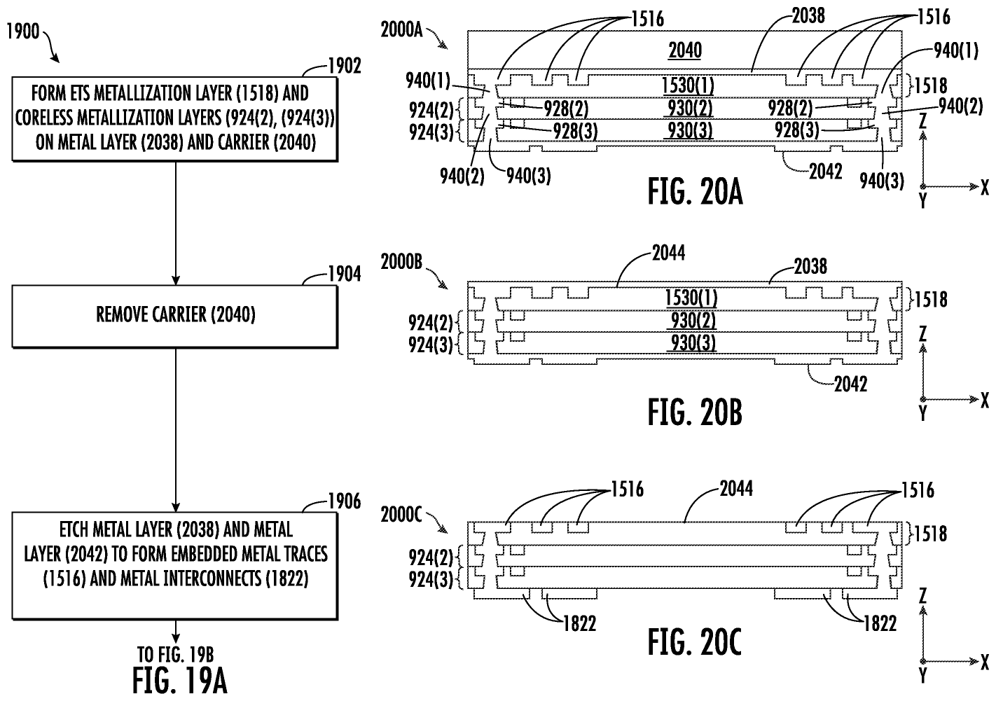

FIG. 18 is a side view of another exemplary IC package 1802 that includes a package substrate 1810 that is similar to the package substrate 1510 in FIG. 15. However, as discussed in more detail below, the package substrate 1810 in FIG. 18 has additional coreless metallization layers 1824(1)-1824(3) that are additionally built up on the coreless metallization layers 924(2)-924(3), below the coreless metallization layer 924(3) to form an asymmetric package substrate 1810. Common elements between the IC package 1502 and package substrate 1510 in FIG. 15 and the IC package 1802 and package substrate 1810 in FIG. 18 are shown with common element numbers. The previous discussion of such common elements is also applicable to the package substrate 1810 in FIG. 18.

In this regard, with reference to FIG. 18, the embedded metal traces 1516 and the DTC interconnects 134 of the arc 130 are disposed in the ETS metallization. layer 1518 that is the die-side outer metallization layer of the package substrate 1810, The ETS metallization layer 1518 is formed on the coreless metallization layer 924(2). The external metal interconnects 128 are disposed through the solder resist layer 1520 adjacent to the ETS metallization layer 1518 and in contact with the embedded metal traces 1516 and DTC interconnects 134 in the ETS metallization layer 1518 to couple the die 108 to the package substrate 1810 and to the .DTC 130. The DTC 130 and the die 108 share a common vertical plane Po in a vertical direction. (X- and Z-axes directions). The DTC 130 is embedded in the ETS metallization layer 1518 and the coreless metallization layers 924(2)-924(3) such that the DTC interconnects 134 of the DTC 130 are disposed in the ETS metallization layer 1518 of the package substrate 1810 directly below respective external metal interconnects 128 in the die-side outer metallization layer 1520 in the vertical direction (Z-axis direction). In this manner, the DTC interconnects 134 can be directly connected to the external metal interconnects 128, which are connected to die interconnects 126, to provide an electrical connection between the DTC 130 and the die 108. This is shown by the connection paths CP₆ labeled in FIG. 18 between the die 108 and the DTC 130. By disposing the DTC 130 in the package substrate 1810 such that the DTC interconnects 134 are disposed in the ETS metallization layer 1518 in this example, the connection path length between the DTC 130 and the die 108, through the external metal interconnects 128 and the die interconnects 126, is minimized to minimize the inductance of the connection. Additional routing in the horizontal direction. (X- and Y-axes directions) is not required to provide the connection paths CP₆ between the DTC 130 to the die 108 in this example.

Also, as shown in FIG. 12, the package substrate 1810 includes the additional, second coreless metallization layers 1824(1)4824(3) that are build-up on the bottom surface 1826 of the coreless metallization layer 924(3). The coreless metallization layers 924(2)-924(3) are disposed between the ETS metallization layer 1518 and the second coreless metallization layers 1824(1)-1824(3). Each of the coreless metallization. layers 1824(1)4824(3) includes respective metal interconnects 1828(1)4828(3) (e.g., metal traces, metal lines, metal posts) that can be connected to adjacent metal interconnects 1828(1)4828(3) in adjacent coreless metallization layers 1824(1)4824(3) to provide signal routing paths in the package substrate 1810. Certain metal interconnects 1828(1) in the coreless metallization layer 1824(1) are connected to the metal interconnects 928(3) in the coreless metallization layer 924(3) to provide a signal routing path through the coreless metallization layers 924(4-924(3) and the ETS metallization layer 1518 to the die 108. Certain metal interconnects 1828(3) in the coreless metallization layer 1224(3) are connected to the metal interconnects 1822 in a bottom, outer solder resist layer 1823 to provide a connection between the package substrate 1810 and external metal interconnects (e.g., solder balls) formed in contact with the metal interconnects 1822.

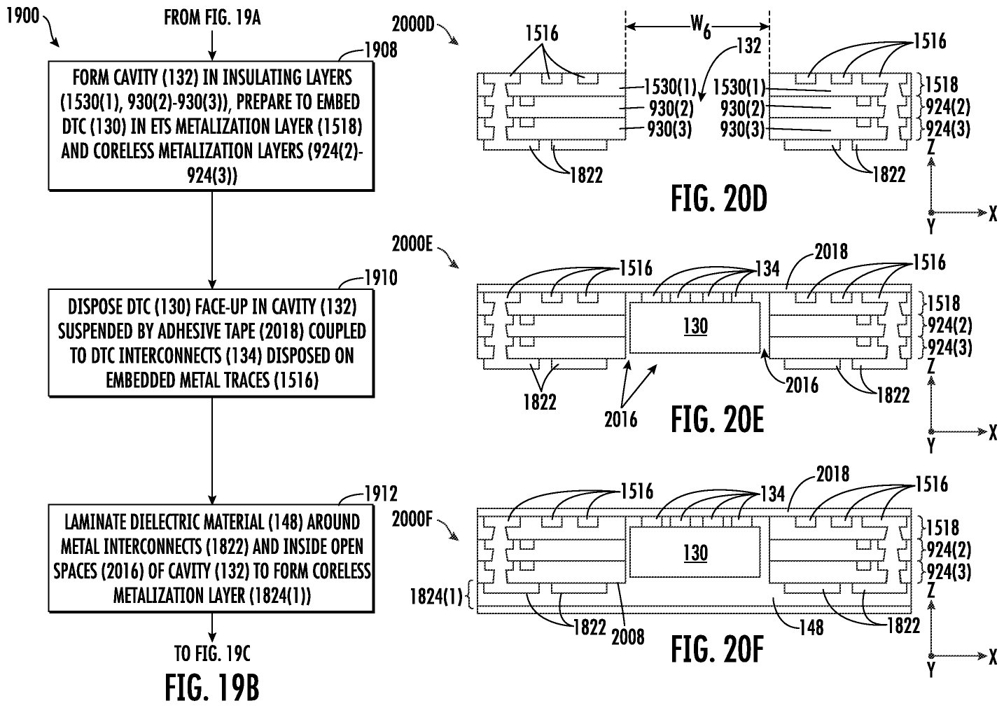

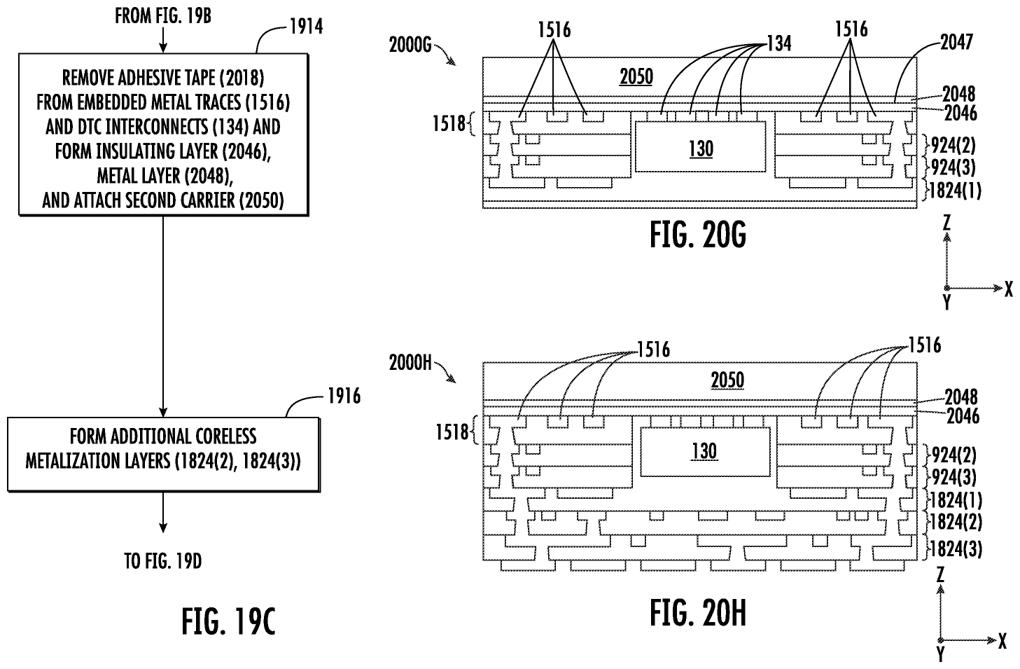

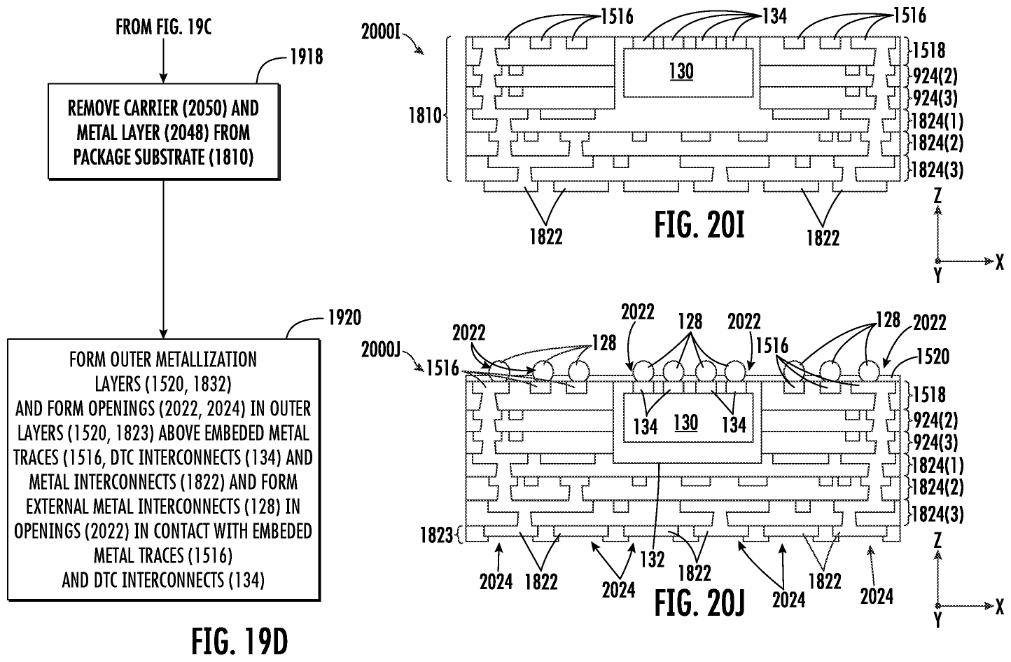

FIGS. 19A-19D is a flowchart illustrating another exemplary fabrication process 1900 of fabricating the package substrate 1810 in FIG. 18. FIGS. 20A-20J are exemplary fabrication stages 2000A-2000J during fabrication of the package substrate 1810 according to the fabrication process 1900 in. FIGS. 19A-19D. The fabrication process 1900 in FIGS. 19A-19D, and as shown in the exemplary fabrication stages 2000A-2000J in FIGS. 20A-20J, will now be discussed in reference to the package substrate 1810 in FIG. 18 as an example.

In this regard, as shown in the exemplary fabrication stage 2000A in FIG. 20A, the ETS metallization layer 1518 and the coreless metallization layers 924(2), 924(3) are formed on a metal layer 2038 that is attached to a carrier 2040 and stacked on top of each other in the vertical direction (Z-axis direction) (block 1902 in FIG. 19A). The ETS metallization layer 1518 and the coreless metallization layers 924(2), 924(3) can be formed using lamination processes. The carrier 2040 allows the ETS metallization layer 1518 and the coreless metallization layers 924(2), 924(3) to be processed to form the embedded metal traces 1516 and metal interconnects 928(2), 928(3) interconnected by respective vias 940(1)-940(3). For example, the ETS metallization layer 1518 and the coreless metallization layers 924(2), 924(3) may be drilled with a metal material disposed in the drilled openings to form the vias 940(1)-940(3) and which provides a residual metal layer 2042 on the coreless metallization layer 924(3). Next, as shown in the exemplary fabrication stage 2000B in FIG. 20B, the carrier 2040 is detached to prepare the ETS metallization layer 1518 and the coreless metallization layers 924(2), 924(3) to be processed (block 1904 in FIG. 19A). As shown in the exemplary fabrication stage 2000C in FIG. 20C, the metal layer 2038 and the metal layer 2042 are etched to expose and planarize the embedded metal traces 1516 with the top surface 2044 of the ETS metallization layer 1518 and to expose and planarize the metal interconnects 1822 (block 1906 in FIG. 19A).

As shown in the exemplary fabrication stage 2000D in FIG. 20D, to prepare to embed the DTC 130 in the ETS metallization layer 1518 and the coreless metallization layers 924(2)-924(3), the cavity 132 is formed in the ETS metallization layer 1518 and the coreless metallization layers 924(2)-924(3) (block 1908 in FIG. 19B). The cavity 132 can be formed in the insulating layer 1530(1) of the ETS metallization layer 1518 and the insulating layers 930(2)-930(3) of the coreless metallization layers 924(2)-924(3) by lithography patterning and etching or by drilling as examples. The width W₆ of the cavity 132 should be formed so that the arc 130 can be disposed width-wise in the horizontal direction (X- and Y-axes directions) inside the cavity 132 and with a tolerance of open spaces 2016 (as shown in exemplary fabrication stage 2000E in FIG. 20E) on the sides of the DTC 130 so that a dielectric material can be disposed inside the open spaces 2016 to insulate the DTC 130 in the ETS metallization layer 1518 and the coreless metallization layers 924(2)-924(3). The arc 130 was fabricated as a separate component in a separate process in this example.

As shown in the exemplary fabrication stage 2000E in FIG. 20E, the DTC 130 is disposed in the cavity 132 formed in the insulating layer 1530(1) of the ETS metallization layer 1518 and the insulating layers 930(2)-930(3) of the coreless metallization layers 924(2)-924(3) to prepare for embedding the DTC 130 in the ETS metallization layer 1518 and the coreless metallization layers 924(2)-924(3) (block 1910 in FIG. 19B). The DTC 130 is suspended inside the cavity 132 in this example so that a dielectric material can then be disposed around the open spaces 2016 around the DTC 130 to insulate the DTC 130. In this regard, as shown in the exemplary fabrication stage 2000E in FIG. 20E, the DTC 130 and more specifically its DTC interconnects 134, are coupled to an adhesive tape 2018 that is then disposed on the embedded metal traces 1516 in the ETS metallization layer 1516 (block 1910 in FIG. 19B). This suspends the DTC 130 in the cavity 132 in a face-up direction towards the ETS metallization layer 1518. The adhesive tape 2018 is also coupled to the embedded metal traces 1516 of the ETS metallization layer 1518 so that the DTC 130 is supported suspended inside the cavity 132. The DTC interconnects 134 being coupled to the adhesive tape 2018, and the adhesive tape 2018 being disposed over the embedded metal traces 1516, causes the DTC interconnects 134 to be disposed in the same metal layer as the embedded metal traces 1516 in the ETS metallization layer 1518 when later formed.

Then, as shown in the exemplary fabrication stage 2000F in FIG. 20F, while the DTC 130 is suspended face-up in the ETS metallization layer 1518 and the coreless metallization layers 924(2)-924(3), the outer metallization layer 1823 as a solder resist layer is formed on the bottom side 2008 of the coreless metallization layer 924(3) by laminating a dielectric material 148 around the metal interconnects 1822 and inside the open spaces 2016 of the cavity 132 adjacent to the DTC 130 (block 1912 in FIG. 19B). This secures the DTC 130 embedded within the ETS metallization layer 1518 and the coreless metallization layers 924(2)-924(3). Also, using this exemplary fabrication process 1900, the dielectric material 148 that is used to form the coreless metallization layer 1824(1) is also the same dielectric material 148 that bounds the cavity 132 and is disposed around the DTC 130 to insulate the DTC 130. Thus, using this fabrication process 1900, the DTC 130 can be insulated in the cavity 132 using the same fabricating process that is used to form the coreless metallization layer 1824(1) of the package substrate 1810.

Then, as shown in exemplary fabrication stage 2000G in FIG. 20G, since the DTC 130 is secured inside the cavity 132 by the dielectric material 148 of the coreless metallization layer 1224(1), the adhesive tape 2018 shown in exemplary fabrication stage 2000F in FIG. 20F can be removed (block 1914 in FIG. 19C). This is to prepare the insulating layer 2046 to be formed over ETS metallization layer 1518 as shown in the exemplary fabrication stage 2000G in FIG. 20G. The insulating layer 2046 is formed by laminating the dielectric material 2047 on the ETS metallization layer 1518 on the embedded metal traces 1516 and the DTC interconnects 134, and then forming an outer metal layer 2048 on the metallization layer 1218 (block 1914 in FIG. 19C). The dielectric material 2047 that forms the insulating layer 2046, the metal layer 2048, and the carrier can be laminated on the ETS metallization layer 1518 at the same time. A carrier 2050 is then formed and attached on the metal layer 2048 so that the package substrate 1810 can be handled to form the additional coreless metallization layers 1824(2), 1824(3) and the outer metallization layer 1223 as shown in the exemplary fabrication stage 2000H in FIG. 20H (block 1916 in FIG. 19C). Then, as shown in exemplary fabrication stage 2000I in FIG. 20I, the carrier 2050 and metal layer 2048 are removed and dielectric material of the metallization layer 1218 is processed to be thinned (block 1918 in FIG. 19D),

Then, as shown in the exemplary fabrication stage 2000J in FIG. 20I, the solder resist layer 1520 is disposed on the metallization layer 1218 to prepare for a bumping process. The lower solder resist layer 1823 is also formed on the bottom coreless metallization layer 1824(3) (block 1920 in FIG. 19D). Note that the outer metallization layer 1223 could be formed at the same time as the solder resist layer 1520. The bumping process is performed to form the external metal interconnects in the openings 2022, 2024 of the respective outer die-side layer, solder resist layer 1520 and solder resist layer 1823 of the package substrate 1810 above the respective metal traces 1516, DTC interconnects 134 and metal interconnects 1822 (block 1920 in FIG. 19D). The openings 2022, 2024 could be formed in the respective outer die-side layer, solder resist layer 1520 and solder resist layer 1823 at the same time. The bumping process forms the external metal interconnects 128 that are coupled to the respective embedded metal traces 1516 and DTC interconnects 134 in the outer metallization layer 1520 as shown in the exemplary fabrication stage in FIG. 20I (block 1920 in FIG. 19D). The external metal interconnects 128 can be formed as solder balls, solder joints, metal posts, or other interconnects. As discussed above with reference to FIG. 18, the DTC interconnects 134 being disposed face-up towards the die-side outer metallization layer 1520 and disposed in the ETS metallization layer 1518 allows the DTC interconnects 134 to be directly coupled to the formed external metal interconnects 128 to provide a connection to die interconnects 126 of a die 108 that is disposed adjacent to the outer metallization layer 1520 of the package substrate 1810 when the IC package 1802 in FIG. 18 is formed. This is to minimize the connection path length between the die 108 and the DTC 130 in the package substrate 1810.

Note that the terms “top” and “upper,” and “bottom” and “lower” are relative terms to each other and not necessarily limited to a component described as a “top” component being above or below another component described as a “bottom” component. Also note that a component described as “disposed in” a layer or package substrate herein is not limited to such component being fully disposed in such layer or package substrate. Also note that the term “external” as used here is to describe a component with regard to a package substrate is a component that that is fully or partially exposed from an outer surface the package substrate.

IC packages that employ a package substrate include a DTC embedded face-up towards a die in the package substrate and disposed underneath the die in a vertical direction, to minimize the connection path length between the DTC and the die, including but not limited to the package substrates in FIGS. 1A-1B, 6, 9, 12, 15, and 18, and according to, but not limited to, any of the exemplary fabrication processes in FIGS. 4A-5I, 7A-81, 10A-11I, 13A-14I, 16A-17I, and 19A-20J, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

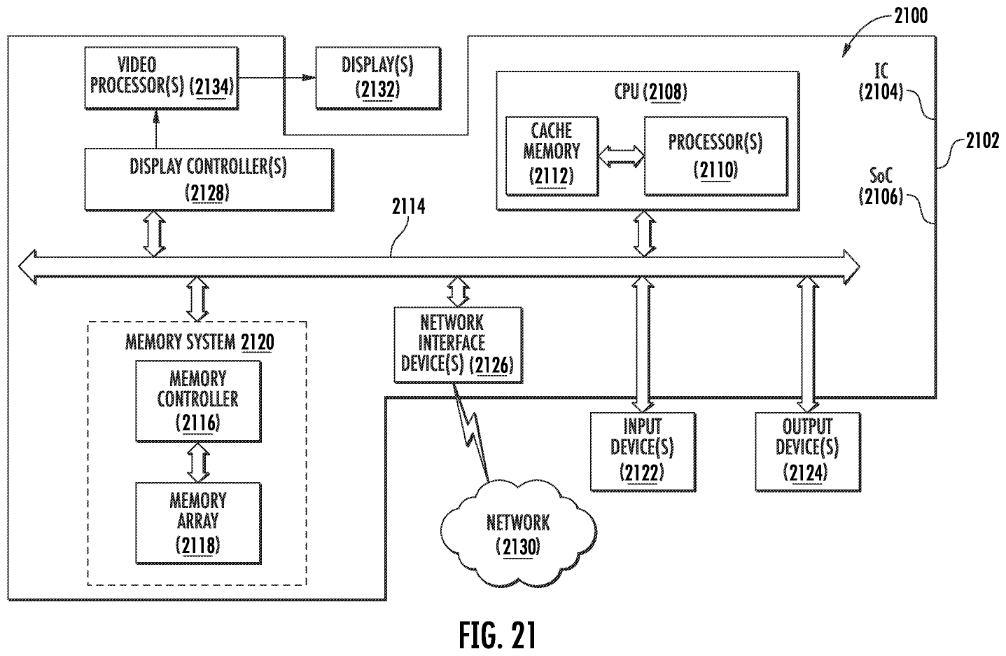

In this regard, FIG. 2I illustrates an example of a processor-based system 2100 including a circuit that can be provided in one or more IC packages 2102(1)-2102(5). The IC packages 2102(1)-2102(5) can employ a package substrate includes a DTC embedded face-up towards a die in the package substrate and disposed underneath the die in a vertical direction, to minimize the connection path length between the DTC and the die, including but not limited to the package substrates in FIGS. 1A-1B, 6, 9, 12, 15, and 18, and according to, but not limited to, any of the exemplary fabrication processes in FIGS. 4A-5I, 7A-8I, 10A-11I, 13A-14I, 16A-17I, and 19A-20J. In this example, the processor-based system 2100 may be formed as an IC 2104 in an IC package 2102 and as a system-on-a-chip (SoC) 2106. The processor-based system 2100 includes a central processing unit (CPU) 2108 that includes one or more processors 2110, which may also be referred to as CPU cores or processor cores. The CPU 2108 may have cache memory 2112 coupled to the CPU 2108 for rapid access to temporarily stored data. The CPU 2108 is coupled to a system bus 2114 and can intercouple master and slave devices included in the processor-based system 2100. As is well known, the CPU 2108 communicates with these other devices by exchanging address, control, and data information over the system bus 2114. For example, the CPU 2108 can communicate bus transaction requests to a memory controller 2116, as an example of a slave device. Although not illustrated in FIG. 21, multiple system buses 2114 could be provided, wherein each system bus 2114 constitutes a different fabric.

Other master and slave devices can be connected to the system bus 2114. As illustrated in FIG. 21, these devices can include a memory system 2120 that includes the memory controller 2116 and a memory array(s) 2118, one or more input devices 2122, one or more output devices 2124, one or more network interface devices 2126, and one or more display controllers 2128, as examples. Each of the memory system(s) 2120, the one or more input devices 2122, the one or more output devices 2124, the one or more network interface devices 2126, and the one or more display controllers 2128 can be provided in the same or different IC packages 2102. The input device(s) 2122 can include any type of input device, including, but not limited to, input keys, switches, voice processors, etc. The output device(s) 2124 can include any type of output device, including, but not limited to, audio, video, other visual indicators, etc. The network interface device(s) 2126 can be any device configured to allow exchange of data to and from a network 2130. The network 2130 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 2126 can be configured to support any type of communications protocol desired.

The CPU 2108 may also be configured to access the display controller(s) 2128 over the system bus 2114 to control information sent to one or more displays 2132. The display controller(s) 2128 sends information to the display(s) 2152 to be displayed via one or more video processors 2134, which process the information to be displayed into a format suitable for the displays) 2132. The display controller(s) 2128 and video processor(s) 2134 can be included as ICs in the same or different IC packages 2102, and in the same or different package 2102 containing the CPU 2108, as an example. The display(s) 2132 can include any type of display, including, but not limited to, a cathode ray tube (CRT), a liquid crystal display (LCD), a plasma display, a light emitting diode (LED) display, etc.

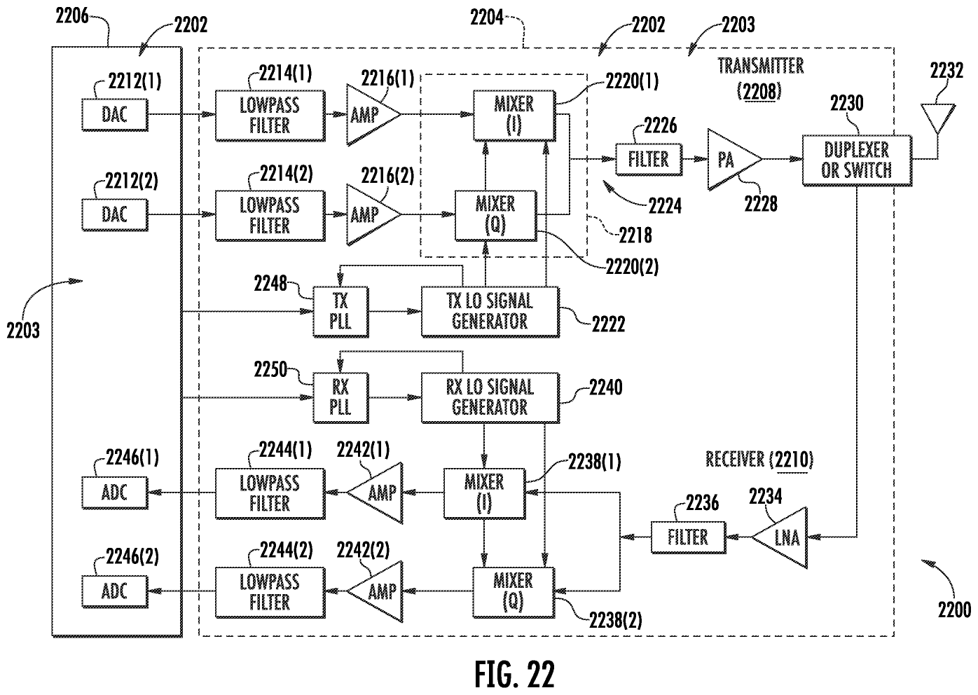

FIG. 22 illustrates an exemplary wireless communications device 2200 that includes radio-frequency (RF) components formed from one or more ICs 2202, wherein any of the ICs 2202 can be included in an IC package 2203 that employs a package substrate includes a DTC embedded face-up towards a die in the package substrate and disposed underneath the die in a vertical direction, to minimize the connection path length between the DTC and the die, including but not limited to the package substrates in FIGS. 1A-1B, 6, 9, 12, 15, and 18, and according to, but not limited to, any of the exemplary fabrication processes in FIG. 4A-5I, 7A-81, 10A-11I, 13A-14I, 16A-17I, and 19A-20J. The IC package 2203 employs a supplemental metal layer with additional metal interconnects coupled to embedded metal traces in a die-side ETS metallization layer of a package substrate to avoid or reduce metal density mismatch between the die-side ETS metallization layer and another metallization layer(s) in the package substrate, including, but not limited to, the package substrates in FIGS. 3A-6B, and 9A-9I and according to the exemplary fabrication processes in FIGS. 7-8E, and according to any aspects disclosed herein. The wireless communications device 2200 may include or be provided in any of the above-referenced devices, as examples. As shown in FIG. 22, the wireless communications device 2200 includes a transceiver 2204 and a data processor 2206. The data processor 2206 may include a memory to store data and program codes. The transceiver 2204 includes a transmitter 2208 and a receiver 2210 that support bi-directional communications. In general, the wireless communications device 2200 may include any number of transmitters 2208 and/or receivers 2210 for any number of communication systems and frequency bands. All or a portion of the transceiver 2204 may be implemented on one or more analog ICs, RF ICs (RFICs), mixed-signal ICs, etc.

The transmitter 2208 or the receiver 2210 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 2210. In the direct-conversion architecture, a signal is frequency-converted between RF and baseband in one stage. The super-heterodyne and direct-conversion architectures may use different circuit blocks and/or have different requirements. In the wireless communications device 2200 in FIG. 22, the transmitter 2208 and the receiver 2210 are implemented with the direct-conversion architecture.

In the transmit path, the data processor 2206 processes data to be transmitted and provides I and Q analog output signals to the transmitter 2208. In the exemplary wireless communications device 2200, the data processor 2206 includes digital-to-analog converters (DACs) 2212(1), 2212(2) for converting digital signals generated by the data processor 2206 into the I and Q analog output signals (e.g., I and Q output currents) for further processing.

Within the transmitter 2208, lowpass filters 2214(1), 2214(2) filter the I and Q analog output signals, respectively, to remove undesired signals caused by the prior digital-to-analog conversion. Amplifiers (AMPs) 2216(1), 2216(2) amplify the signals from the lowpass filters 2214(1), 2214(2), respectively, and provide I and Q baseband signals. An upconverter 2218 upconverts the I and Q baseband signals with I and Q transmit (TX) local oscillator (LO) signals through mixers 2220(1), 2220(2) from a TX LO signal generator 2222 to provide an upconverted signal 2224. A filter 2226 filters the upconverted signal 2224 to remove undesired signals caused by the frequency up-conversion as well as noise in a receive frequency band. A power amplifier (PA) 2228 amplifies the upconverted signal 2224 from the filter 2226 to obtain the desired output power level and provides a transmit RF signal. The transmit RF signal is routed through a duplexer or switch 2230 and transmitted via an antenna 2232.

In the receive path, the antenna 2232 receives signals transmitted by base stations and provides a received RF signal, which is routed through the duplexer or switch 2230 and provided to a low noise amplifier (LNA) 2234. The duplexer or switch 2230 is designed to operate with a specific receive (RX)-to-TX duplexer frequency separation, such that RX signals are isolated from TX signals. The received RF signal is amplified by the LNA 2234 and filtered by a filter 2236 to obtain a desired RF input signal. Down-conversion mixers 2238(1), 2238(2) mix the output of the filter 2236 with I and Q RX LO signals (i.e., LO_I and LO_Q) from an RX LO signal generator 2240 to generate and Q baseband signals. The I and Q baseband signals are amplified by AMPs 2242(1), 2242(2) and further filtered by lowpass filters 2244(1), 2244(2) to obtain I and Q analog input signals, which are provided to the data processor 2206. In this example, the data processor 2206 includes analog-to-digital converters (ADCs) 2246(1), 2246(2) for converting the analog input signals into digital signals to be further processed by the data processor 2206.

In the wireless communications device 2200 of FIG. 22, the TX LO signal generator 2222 generates the 1 and Q TX LO signals used for frequency up-conversion, while the RX L( )signal generator 2240 generates the I and Q RX LO signals used for frequency down-conversion. Each LO signal is a periodic signal with a particular fundamental frequency. A TX phase-locked loop (PLL) circuit 2248 receives timing information from the data processor 2206 and generates a control signal used to adjust the frequency and/or phase of the TX LO signals from the TX LO signal generator 2222. Similarly, an RX I′LL circuit 2250 receives timing information from the data processor 2206 and generates a control signal used to adjust the frequency and/or phase of the RX LO signals from the RX LO signal generator 2240.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC) package, comprising:
   a die comprising a plurality of die interconnects; and
   a package substrate, comprising:
      a metallization layer adjacent to the die in a vertical direction; and
      a plurality of external metal interconnects coupled to the metallization layer; and
   a deep trench capacitor (DTC) disposed in the package substrate, the DTC comprising a plurality of DTC interconnects disposed in the metallization layer;
   each external metal interconnect among the plurality of external metal interconnects coupled to a die interconnect among the plurality of die interconnects and a DTC interconnect among the plurality of DTC interconnects.
2. The IC package of clause 1, wherein the DTC and the die share a common plane in the vertical direction.
3. The IC package of any of clauses 1 or 2, wherein:
   the package substrate further comprises a cavity bounded by a dielectric material; and
   the DTC is disposed inside the cavity.
4. The IC package of any of clauses 1-3, wherein:
   the DTC comprises a first face disposed in the metallization layer; and
   the plurality of DTC interconnects are exposed from the first face and disposed in the metallization layer.
5. The IC package of any of clauses 1-4, wherein the metallization layer comprises a solder resist layer.
6. The IC package of any of clauses 1-4, wherein the metallization layer comprises a core substrate.
7. The IC package of any of clauses 1-4, wherein the metallization layer comprises a careless metallization layer.
8. The IC package of any of clauses 1-4, wherein the metallization layer comprises an embedded trace substrate (ETS) metallization layer.
9. The IC package of clause 5, wherein:
   the solder resist layer further comprises a dielectric material; and
   the plurality of external metal interconnects are disposed in the dielectric material of the solder resist layer.
10. The IC package of clause 9, wherein:
   the package substrate further comprises a cavity bounded on a first side by the solder resist layer and bounded on a plurality of other sides by a second dielectric material that is of the dielectric material of the solder resist layer; and
   the DTC is disposed inside the cavity.
11. The IC package of clause 6, wherein:
   the package substrate further comprises one or more second metallization layers adjacent to the core substrate; and
   the core substrate is disposed between the die and the one or more second metallization layers.
12. The IC package of clause 11, wherein:
   the core substrate comprises a first dielectric material;
   the one or more second metallization layers comprise a second dielectric material;
   the package substrate further comprises a cavity bounded on a first side by the first dielectric material of the core substrate and bounded by a third dielectric material that is of the second dielectric material of the one or more second metallization layers; and
   the DTC is disposed inside the cavity.
13. The IC package of clause 7, wherein:
   the package substrate further comprises one or more second metallization layers disposed adjacent to the metallization layer in the vertical direction; and
   the coreless metallization layer is disposed between the die and the one or more second metallization layers.
14. The IC package of clause 13, wherein:
   the metallization layer further comprises a first dielectric material;
   the one or more second metallization layers each comprise a second dielectric material;
   the package substrate further comprises a cavity bounded on a first side by the first dielectric material of the coreless metallization layer and bounded by a third dielectric material that is of the second dielectric material of the one or more second metallization layers; and
   the arc is disposed inside the cavity.
15. The IC package of clause 8, wherein:

the ETS metallization layer comprises an insulating layer and plurality of metal traces embedded in the insulating layer; and the plurality of DTC interconnects are disposed in the insulating layer of the ETS metallization layer.
16. The IC package of clause 15, wherein:

the package substrate further comprises one or more second metallization layers disposed adjacent to the ETS metallization layer in the vertical direction; and
the ETS metallization layer is disposed between the die and the one or more second metallization layers.
17. The IC package of clause 16, wherein:
   the insulating layer of the ETS metallization layer comprises a first dielectric material;
   the one or more second metallization layers comprise a second dielectric material;
   the package substrate further comprises a cavity bounded on a first side by the first dielectric material of the insulating layer and bounded by a third dielectric material that is of the second dielectric material of the one or more second metallization layers; and
   the arc is disposed inside the cavity.
18. The package substrate of any of clauses 1-17 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
19. A method of fabricating an integrated circuit (IC) package, comprising:
   fabricating a package substrate, comprising:
      forming a metallization layer; and
      forming a plurality of external metal interconnects coupled to the metallization layer;
   disposing a deep trench capacitor (DTC) comprising a plurality of DTC interconnects in the package substrate such that the plurality of DTC interconnects are disposed in the metallization layer;
   coupling each DTC interconnect among the plurality of DTC interconnects to an external metal interconnect among the plurality of external metal interconnects;
   disposing a die adjacent to the metallization layer in a vertical direction, the die comprising a plurality of die interconnects; and
   coupling each of the plurality of die interconnects to an external metal interconnect among the plurality of external metal interconnects.
20. The method of clause 19, wherein fabricating the package substrate further comprises forming one or more second metallization layers disposed adjacent to the metallization layer in the vertical direction, wherein the metallization layer is disposed between the die and the one or more second metallization layers.
21. The method of any of clauses 19-20, wherein disposing the DTC in the package substrate, further comprises disposing the plurality of DTC interconnects in the metallization layer comprising a solder resist layer.

22. The method of any of clauses 19-20, wherein disposing the DTC in the package substrate further comprises disposing the plurality of DTC interconnects in the metallization layer comprising a coreless metallization layer.
23. The method of any of clauses 19-20, wherein disposing the DTC in the package substrate further comprises disposing the plurality of arc interconnects in the metallization layer comprising an embedded trace substrate (ETS) metallization layer,
24. The method of any of clauses 19-23, wherein disposing the die further comprises disposing the die to share a common plane with the DTC in the vertical direction.
25. The method of any of clauses 19-24, further comprising forming a cavity in the metallization layer; and
   wherein disposing the DTC in the metallization layer comprises disposing the DTC in the cavity in the metallization layer.
26. The method of clause 25, wherein forming the cavity in the metallization layer comprises forming the cavity in the metallization layer that is bounded by a dielectric material of the metallization layer.
27. The method of clause 25, further comprising:
   forming a plurality of metal interconnects in the metallization layer comprising a core substrate; and
   wherein disposing the DTC in the cavity in the metallization layer comprises disposing the DTC in the cavity in the core substrate and further comprises:
      providing the DTC with the plurality of DTC interconnects coupled to a tape; and.
      coupling the tape to the plurality of metal interconnects in the core substrate to suspend the DTC in the cavity.
28. The method of clause 25, further comprising:
   forming a plurality of metal interconnects in the metallization layer comprising a coreless metallization layer; and
   wherein disposing the DTC in the cavity in the metallization layer comprises disposing the DTC in the cavity in the coreless metallization layer and further comprises:
      providing the DTC with the plurality of DTC interconnects coupled to a tape; and
      coupling the tape to the plurality of metal interconnects in the coreless metallization layer to suspend the DTC in the cavity.
29. The method of clause 25, further comprising:
   forming a plurality of metal interconnects in the metallization layer comprising an embedded trace substrate (ETS) metallization layer; and
   wherein disposing the DTC in the cavity in the metallization layer comprises disposing the DTC in the cavity in the ETS metallization layer and further comprises:
      providing the DTC with the plurality of DTC interconnects coupled to a tape; and
      coupling the tape to the plurality of metal interconnects in the ETS metallization layer to suspend the DTC in the cavity.

What is claimed is:

1. An integrated circuit (IC) package, comprising:
a die comprising a plurality of die interconnects; and
a package substrate, comprising:
a metallization layer adjacent to the die in a vertical direction; and
a plurality of external metal interconnects coupled to the metallization layer; and.
a deep trench capacitor (DTC) disposed in the package substrate, the DTC comprising a plurality of DTC interconnects disposed in the metallization layer;
each external metal interconnect among the plurality of external metal interconnects coupled to a die interconnect among the plurality of die interconnects and a DTC interconnect among the plurality of DTC interconnects.

2. The IC package of claim 1, wherein the DTC and the die share a common plane in the vertical direction.

3. The IC package of claim 1, wherein:
the package substrate further comprises a cavity bounded by a dielectric material; and
the DTC is disposed inside the cavity.

4. The IC package of claim 1, wherein:
the DTC comprises a first face disposed in the metallization layer; and
the plurality of DTC interconnects are exposed from the first face and disposed in the metallization layer.

5. The IC package of claim 1, wherein the metallization layer comprises a solder resist layer.

6. The IC package of claim 1, wherein the metallization layer comprises a core substrate.

7. The IC package of claim 1, wherein the metallization layer comprises a careless metallization layer.

8. The IC package of claim 1, wherein the metallization layer comprises an embedded trace substrate (EIS) metallization layer.

9. The IC package of claim 5, wherein:
the solder resist layer further comprises a dielectric material; and
the plurality of external metal interconnects are disposed in the dielectric material of the solder resist layer.

10. The IC package of claim 9, wherein:
the package substrate further comprises a cavity bounded on a first side by the solder resist layer and bounded on a plurality of other sides by a second dielectric material that is of the dielectric material of the solder resist layer; and
the DTC is disposed inside the cavity.

11. The IC package of claim 6, wherein:
the package substrate further comprises one or more second metallization layers adjacent to the core substrate; and
the core substrate is disposed between the die and the one or more second metallization layers.

12. The IC package of claim 11, wherein:
the core substrate comprises a first dielectric material;
the one or more second metallization layers comprise a second dielectric material;
the package substrate further comprises a cavity bounded on a first side by the first dielectric material of the core substrate and bounded by a third dielectric material that is of the second dielectric material of the one or more second metallization layers; and
the DTC is disposed inside the cavity.

13. The IC package of claim 7, wherein:
the package substrate further comprises one or more second metallization layers disposed adjacent to the metallization layer in the vertical direction; and
the coreless metallization layer is disposed between the die and the one or more second metallization layers.

14. The IC package of claim 13, wherein:
the metallization layer further comprises a first dielectric material;
the one or more second metallization layers each comprise a second dielectric material;
the package substrate further comprises a cavity bounded on a first side by the first dielectric material of the coreless metallization layer and bounded by a third dielectric material that is of the second dielectric material of the one or more second metallization layers; and
the arc is disposed inside the cavity.

15. The IC package of claim 8, wherein:
the ETS metallization layer comprises an insulating layer and plurality of metal traces embedded in the insulating layer; and
the plurality of DTC interconnects are disposed in the insulating layer of the ETS metallization layer.

16. The IC package of claim 15, wherein:
the package substrate further comprises one or more second metallization layers disposed adjacent to the ETS metallization layer in the vertical direction; and
the ETS metallization layer is disposed between the die and the one or more second metallization layers.

17. The IC package of claim 16, wherein:
the insulating layer of the ETS metallization layer comprises a first dielectric material;
the one or more second metallization layers comprise a second dielectric material;
the package substrate further comprises a cavity bounded on a first side by the first dielectric material of the insulating layer and bounded by a third dielectric material that is of the second dielectric material of the one or more second metallization layers; and
the DTC is disposed inside the cavity,

18. The package substrate of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (MD) player; a portable digital video player; an automobile; a vehicle component; an avionics system; a drone; and a multicopter.

19. A method of fabricating an integrated circuit (IC) package, comprising:
fabricating a package substrate, comprising:
forming a metallization layer; and.
forming a plurality of external metal interconnects coupled to the metallization layer;
disposing a deep trench capacitor (DTC) comprising a plurality of DTC interconnects in the package substrate such that the plurality of DTC interconnects are disposed in the metallization layer;
coupling each DTC interconnect among the plurality of DTC interconnects to an external metal interconnect among the plurality of external metal interconnects;
disposing a die adjacent to the metallization layer in a vertical direction, the die comprising a plurality of die interconnects; and
coupling each of the plurality of die interconnects to an external metal interconnect among the plurality of external metal interconnects,

20. The method of claim 19, wherein fabricating the package substrate further comprises forming one or more second metallization layers disposed adjacent to the metallization layer in the vertical direction, wherein the metallization layer is disposed between the die and the one or more second metallization layers.

21. The method of claim 19, wherein disposing the DTC in the package substrate, further comprises disposing the plurality of DTC interconnects in the metallization layer comprising a solder resist layer.

22. The method of claim 19, wherein disposing the DTC in the package substrate further comprises disposing the plurality of DTC interconnects in the metallization layer comprising a coreless metallization layer.

23. The method of claim 19, wherein disposing the DTC in the package substrate further comprises disposing the plurality of DTC interconnects in the metallization layer comprising an embedded trace substrate (ETS) metallization layer.

24. The method of claim 19, wherein disposing the die further comprises disposing the die to share a common plane with the DTC in the vertical direction.

25. The method of claim 19, further comprising forming a cavity in the metallization layer; and
wherein disposing the DTC in the metallization layer comprises disposing the DTC in the cavity in the metallization layer.

26. The method of claim 25, wherein forming the cavity in the metallization layer comprises forming the cavity in the metallization layer that is bounded by a dielectric material of the metallization layer.

27. The method of claim 25, further comprising:
forming a plurality of metal interconnects in the metallization layer comprising a core substrate; and
wherein disposing the DTC in the cavity in the metallization layer comprises disposing the DTC in the cavity in the core substrate and further comprises:
providing the DTC with the plurality of DTC interconnects coupled to a tape; and
coupling the tape to the plurality of metal interconnects in the core substrate to suspend the DTC in the cavity.

28. The method of claim 25, further comprising:
forming a plurality of metal interconnects in the metallization layer comprising a coreless metallization layer; and
wherein disposing the DTC in the cavity in the metallization layer comprises disposing the DTC in the cavity in the coreless metallization layer and further comprises:
providing the DTC with the plurality of DTC interconnects coupled to a tape; and
coupling the tape to the plurality of metal interconnects in the coreless metallization layer to suspend the DTC in the cavity.

29. The method of claim 25, further comprising:
forming a plurality of metal interconnects in the metallization layer comprising an embedded trace substrate (ETS) metallization layer; and
wherein disposing the DTC in the cavity in the metallization layer comprises disposing the DTC in the cavity in the ETS metallization layer and further comprises:
providing the DTC with the plurality of DTC interconnects coupled to a tape; and
coupling the tape to the plurality of metal interconnects in the ELS metallization layer to suspend the DTC in the cavity.
